(19) United States
(12) Patent Application Publication
(10) Pub. No.: US 2024/0363624 A1
(43) Pub. Date: Oct. 31, 2024

(54) VERTICALLY STACKED TRANSISTORS

(71) Applicants: TAIWAN SEMICONDUCTOR MANUFACTURING COMPANY, LTD., Hsinchu (TW); NATIONAL TAIWAN UNIVERSITY, Taipei (TW)

(72) Inventors: Hsin-Cheng LIN, Taipei City (TW); Ching-Wang YAO, New Taipei City (TW); Kung-Ying CHIU, Taoyuan City (TW); Chee-Wee LIU, Taipei City (TW)

(73) Assignees: TAIWAN SEMICONDUCTOR MANUFACTURING COMPANY, LTD., Hsinchu (TW); NATIONAL TAIWAN UNIVERSITY, Taipei (TW)

(21) Appl. No.: 18/307,306

(22) Filed: Apr. 26, 2023

(51) Int. Cl. H01L 27/088; H01L 21/822; H01L 21/8234; H01L 29/06; H01L 29/423; H01L 29/66; H01L 29/775

(52) U.S. Cl. CPC H01L 27/088; H01L 21/8221; H01L 21/823412; H01L 21/823418; H01L 21/823481; H01L 29/0673; H01L 29/42392; H01L 29/66439; H01L 29/775; H03F 3/16

(57) ABSTRACT

A device includes a semiconductor substrate, a first transistor, a second transistor over the first transistor and a first isolation structure. The first transistor is on the semiconductor substrate. The first transistor comprises a first channel, a first source and a first drain. The first source and the first drain are on opposite sides of the first channel. The second transistor comprises a second channel, a second source and a second drain. The second source and the second drain are on opposite sides of the second channel. The first transistor is connected in series with the second transistor. The first isolation structure is vertically between the first drain and the second source.

### BACKGROUND

Semiconductor devices are used in a variety of electronic applications, such as, for example, personal computers, cell phones, digital cameras, and other electronic equipment. Semiconductor devices are typically fabricated by sequentially depositing insulating or dielectric layers, conductive layers, and semiconductor layers of material over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A, 1B, 1C and 1D are a method of manufacturing an integrated circuit including vertically stacked transistors on a semiconductor substrate in accordance with some embodiments of the present disclosure.

FIGS. 2A, 3A, 4A, 5A, 6A, 7A, 8A, 9A, 10A, 11A, 12A, 13A, 14A, 15A, 16A, 17A, 18A, 19A, 20A, 21A, 22A, 23A, 24A, 25A, 26A, 27A, 28A and 29A are top views of the integrated circuit in accordance with some embodiments of the present disclosure.

FIGS. 2B, 3B, 4B, 5B, 6B, 7B, 8B, 9B, 10B, 11B, 12B, 13B, 14B, 15B, 16B, 17B and 18B are cross-sectional views cutting along line A-A′ of FIGS. 2A, 3A, 4A, 5A, 6A, 7A, 8A, 9A, 10A, 11A, 12A, 13A, 14A, 15A, 16A, 17A and 18A, respectively, at various stages in accordance with some embodiments.

FIG. 18C is a cross-sectional view cutting along line B-B′ of FIG. 18A at various stages in accordance with some embodiments.

FIGS. 19B, 20B, 21B, 22B, 23B, 24B, 25B, 26B, 27B, 28B and 29B are cross-sectional views cutting along line B-B′ of FIGS. 19A, 20A, 21A, 22A, 23A, 24A, 25A, 26A, 27A, 28A and 29A, respectively, at various stages in accordance with some embodiments.

FIGS. 19C, 23C, 24C, 26C, 27C, 28C and 29C are cross-sectional views cutting along line A-A′ of FIGS. 23A and 24A, respectively, at various stages in accordance with some embodiments.

FIG. 29D is similar to FIG. 29B, except for labeling circuit reference numbers for discussing about the circuit diagram.

FIG. 29E is an exemplary circuit diagram of the vertically stacked transistors in the integrated circuit of FIGS. 29A-29D in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, “around,” “about,” “approximately,” or “substantially” may mean within 20 percent, or within 10 percent, or within 5 percent of a given value or range. One skilled in the art will realize, however, that the value or range recited throughout the description are merely examples, and may be reduced with the down-scaling of the integrated circuits. Numerical quantities given herein are approximate, meaning that the term “around,” “about,” “approximately,” or “substantially” can be inferred if not expressly stated.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

The gate all around (GAA) transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

As discussed in greater detail below, embodiments of the present disclosure describe an integrated circuit including vertically stacked transistors on a semiconductor substrate. The techniques described herein include forming an isolation structure between epitaxial source/drain regions of vertically stacked transistors to allow the transistors to be connected in series with each other without increasing a footprint of the integrated circuit.

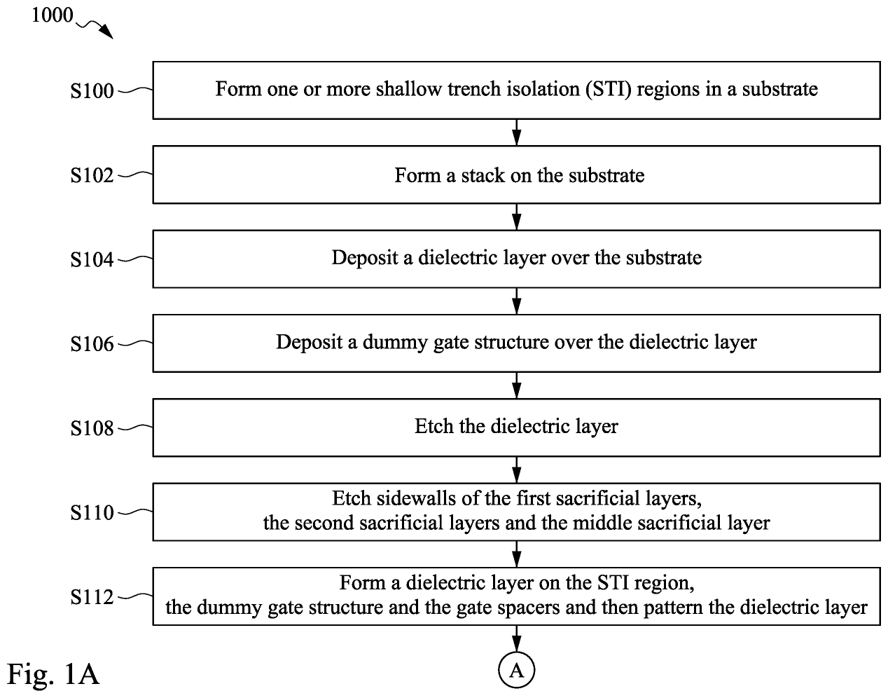

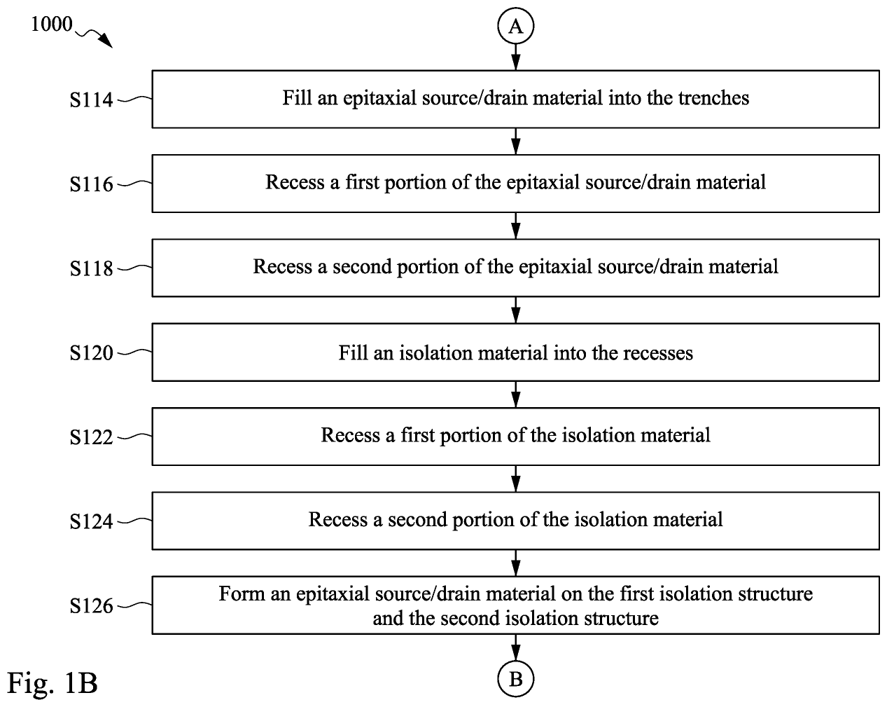

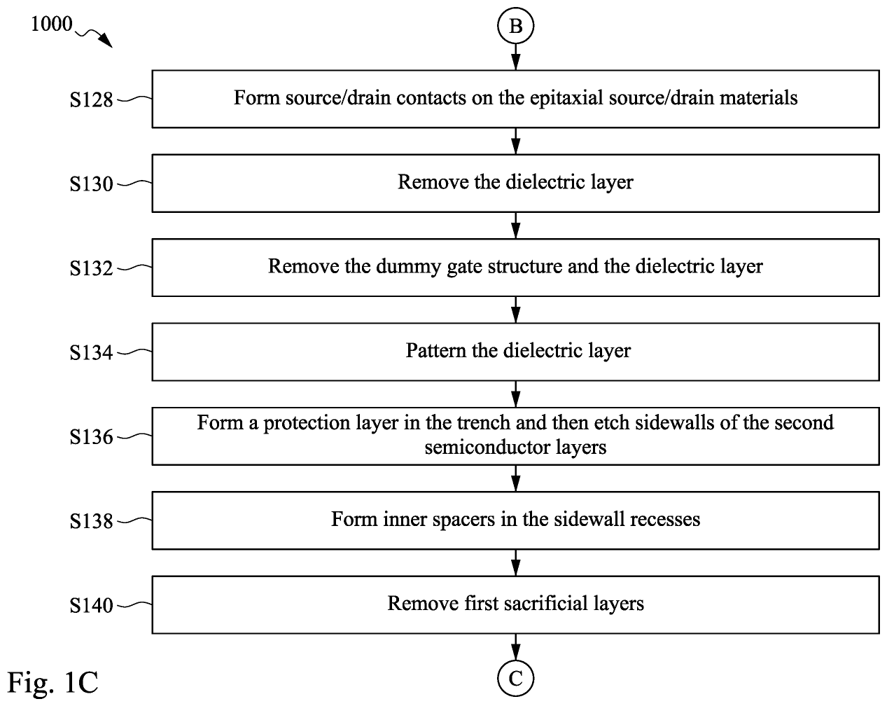

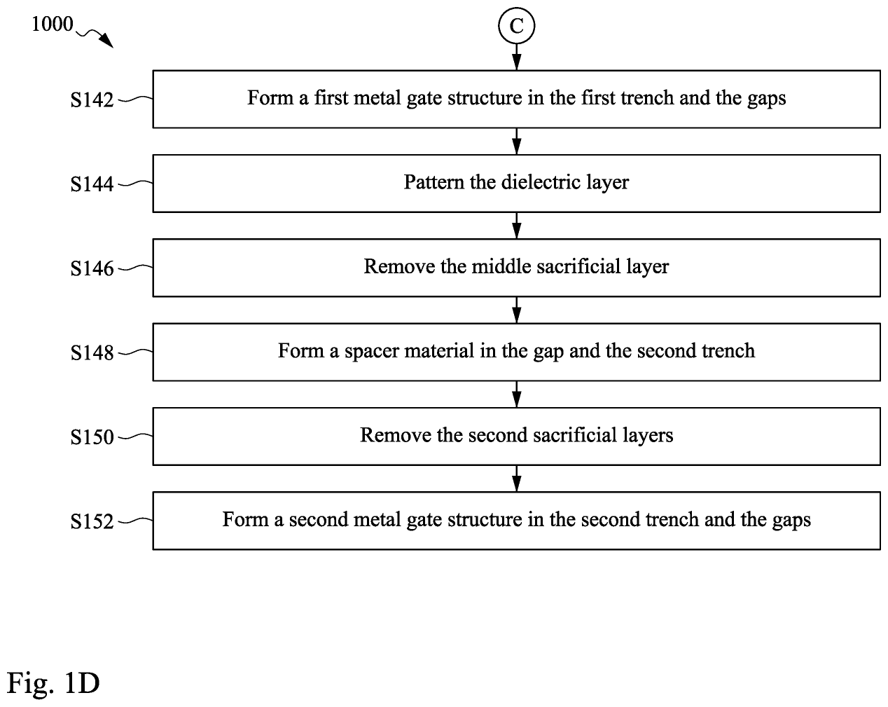

Referring now to FIGS. 1A-1D, illustrated is a flowchart of an exemplary method 1000 for fabrication of an integrated circuit including vertically stacked transistors on a semiconductor substrate in accordance with some embodiments. The method 1000 includes a relevant part of the entire manufacturing process. It is understood that additional operations may be provided before, during, and after the operations shown by FIGS. 1A-1D, and some of the operations described below can be replaced or eliminated for additional embodiments of the method. The order of the operations/processes may be interchangeable. The method 1000 includes fabrication of a semiconductor device. However, the fabrication of the semiconductor device is merely an example for describing the manufacturing process according to some embodiments of the present disclosure.

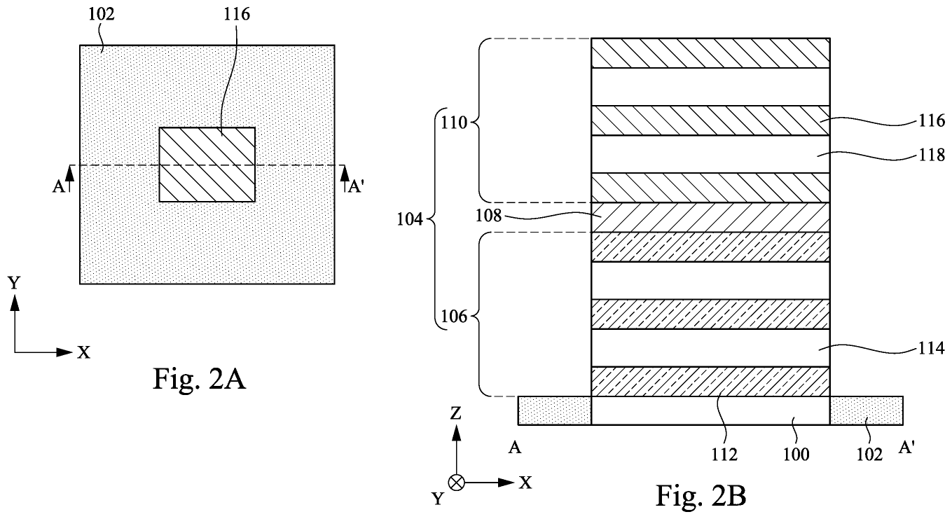

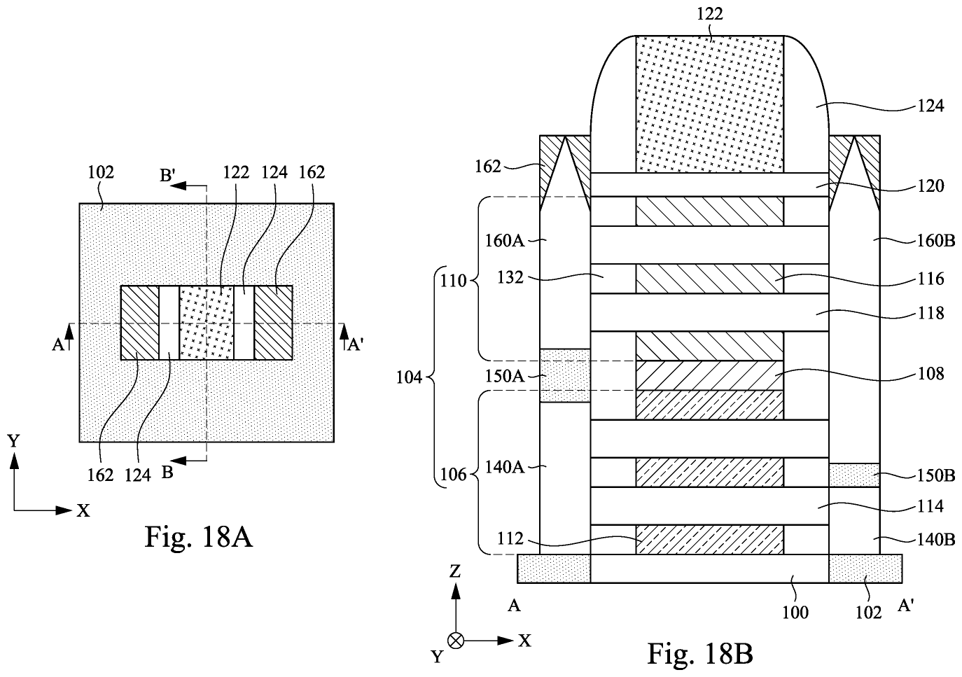

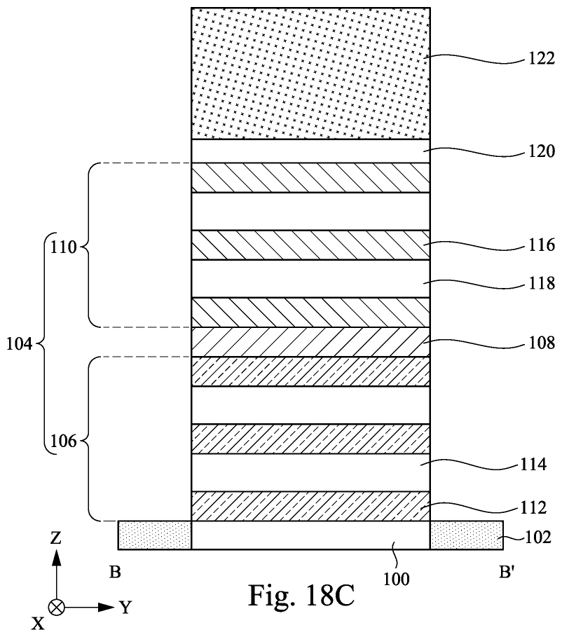

FIGS. 2A to 29C illustrate schematic views of intermediate stages in the formation of vertically stacked transistors in an integrated circuit in accordance with some embodiments of the present disclosure. FIGS. 2A, 3A, 4A, 5A, 6A, 7A, 8A, 9A, 10A, 11A, 12A, 13A, 14A, 15A, 16A, 17A, 18A, 19A, 20A, 21A, 22A, 23A, 24A, 25A, 26A, 27A, 28A and 29A are top views of the integrated circuit in accordance with some embodiments of the present disclosure. FIGS. 2B, 3B, 4B, 5B, 6B, 7B, 8B, 9B, 10B, 11B, 12B, 13B, 14B, 15B, 16B, 17B and 18B are cross-sectional views cutting along line A-A′ of FIGS. 2A, 3A, 4A, 5A, 6A, 7A, 8A, 9A, 10A, 11A, 12A, 13A, 14A, 15A, 16A, 17A and 18A, respectively, at various stages in accordance with some embodiments. FIG. 18C is a cross-sectional view cutting along line B-B′ of FIG. 18A at various stages in accordance with some embodiments.

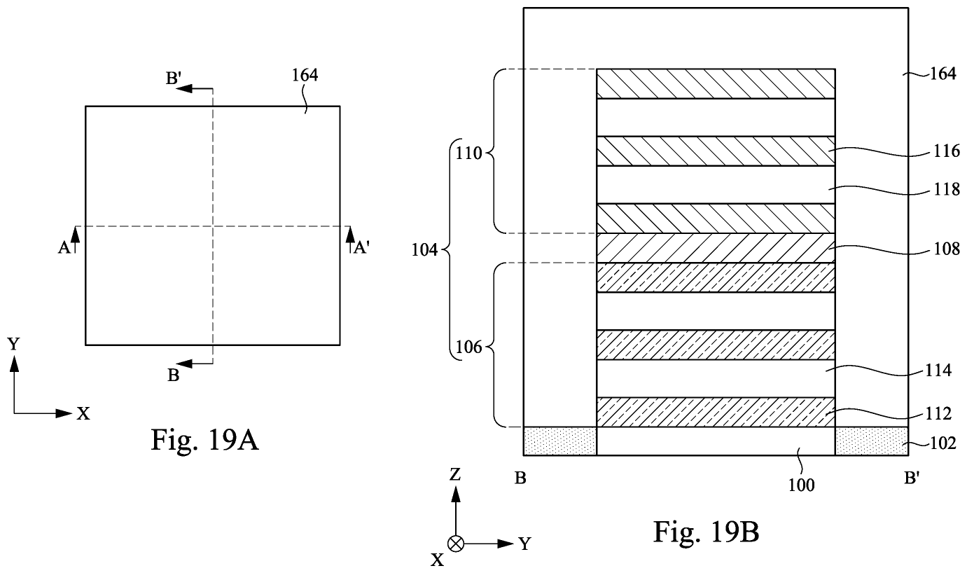

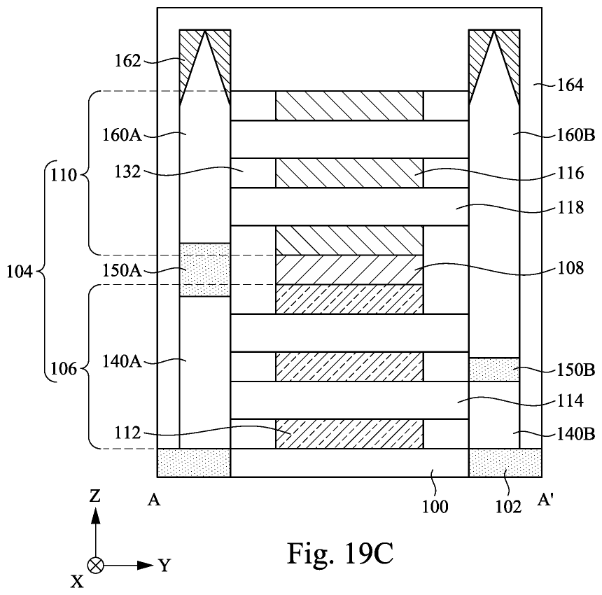

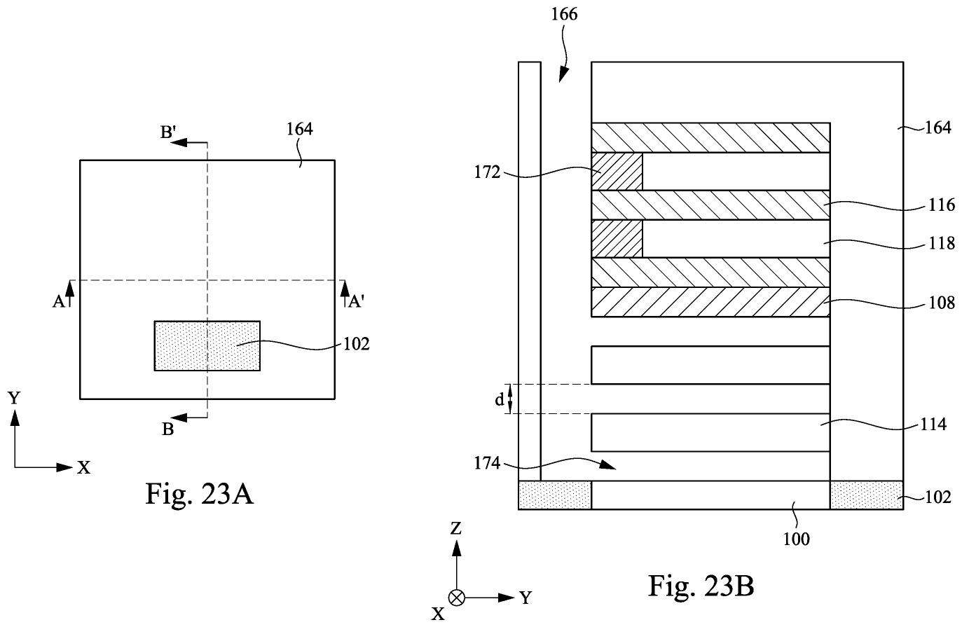

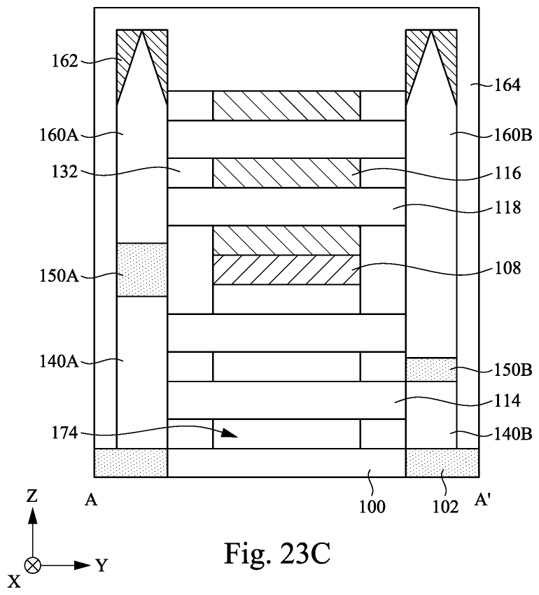

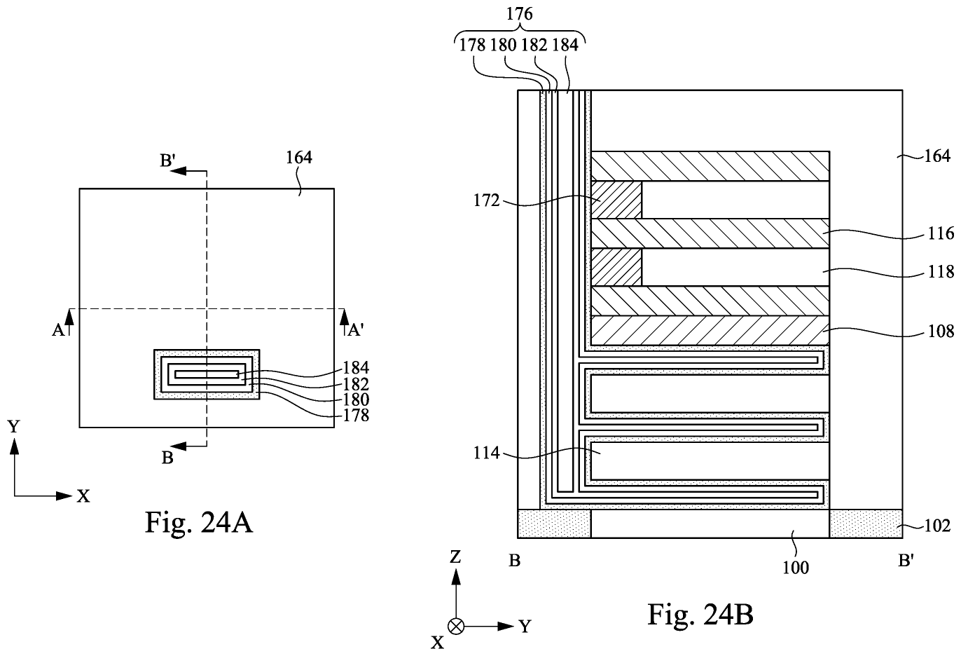

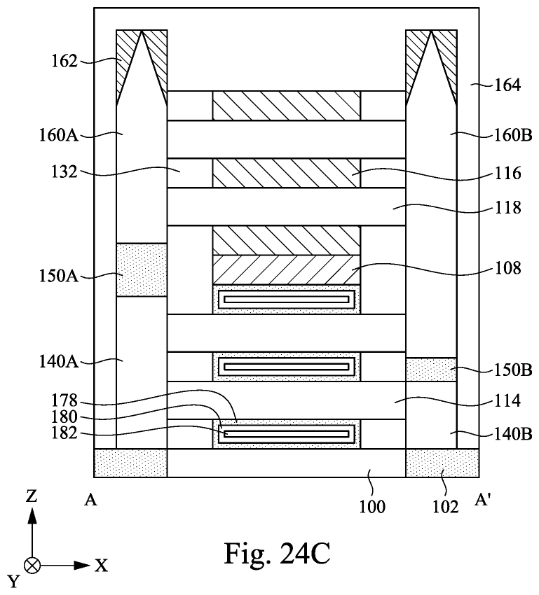

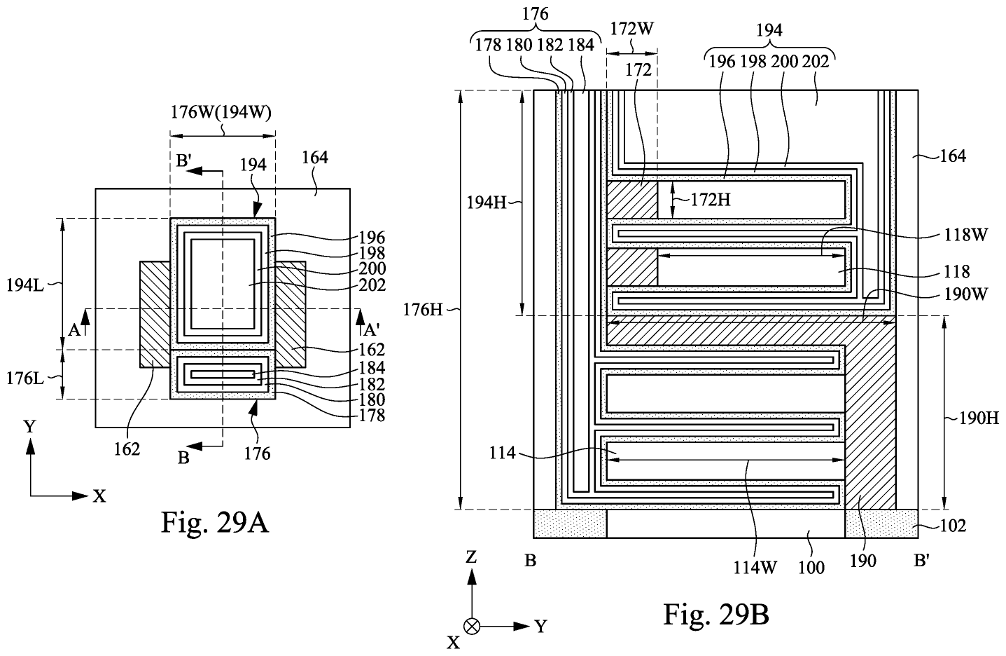

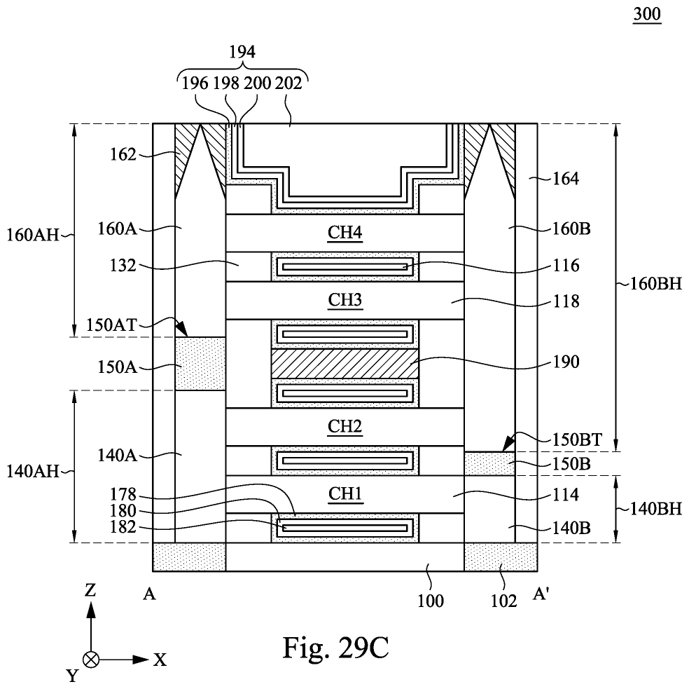

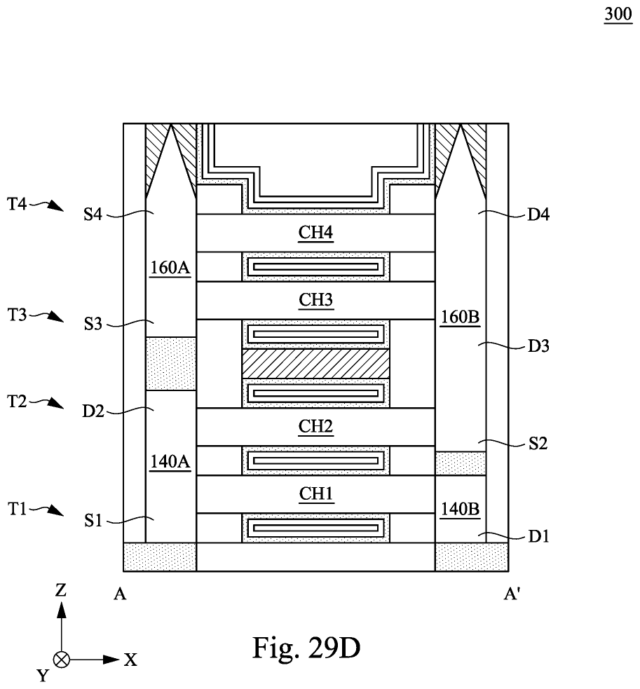

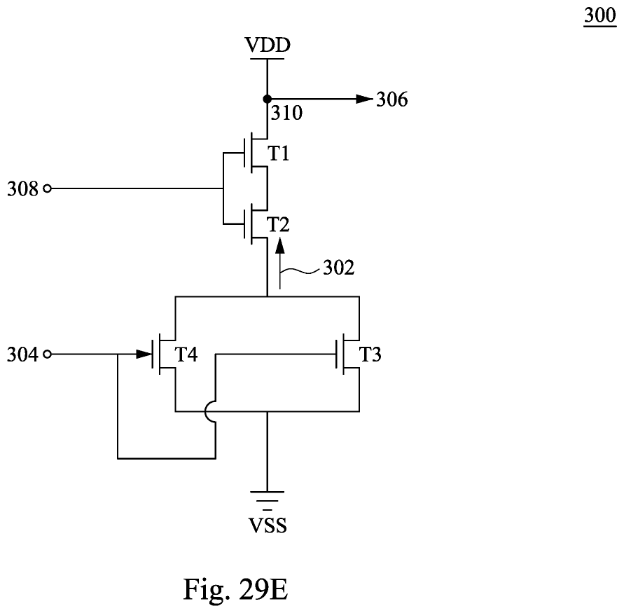

FIGS. 19B, 20B, 21B, 22B, 23B, 24B, 25B, 26B, 27B, 28B and 29B are cross-sectional views cutting along line B-B′ of FIGS. 19A, 20A, 21A, 22A, 23A, 24A, 25A, 26A, 27A, 28A and 29A, respectively, at various stages in accordance with some embodiments. FIGS. 19C, 23C, 24C, 26C, 27C, 28C and 29C are cross-sectional views cutting along line A-A′ of FIGS. 23A and 24A, respectively, at various stages in accordance with some embodiments. FIG. 29E is similar to FIG. 29B, except for labeling circuit elements and omitting structural elements for clarity. An X-Y-Z coordinate system is illustrated in FIGS. 2A-29C and FIG. 29E.

The method 1000 begins at a block S100 where one or more shallow trench isolation (STI) regions are formed in a substrate. With reference to FIGS. 2A and 2B, in some embodiments of block S100, an STI region 102 is formed in a substrate 100. Formation of the STI region 102 includes, by way of example and not limitation, etching the substrate 100 to form one or more trenches, depositing one or more dielectric materials (e.g., silicon oxide) to overfill the trenches in the substrate 100, followed by a CMP process to planarize the one or more STI region 102 with the substrate 100.

In some embodiments, the substrate 100 may be made of a suitable elemental semiconductor, such as silicon, diamond or germanium; a suitable alloy or compound semiconductor, such as Group-IV compound semiconductors (silicon germanium (SiGe), silicon carbide (SiC), silicon germanium carbide (SiGeC), GeSn, SiSn, SiGeSn), Group III-V compound semiconductors (e.g., gallium arsenide, indium gallium arsenide InGaAs, indium arsenide, indium phosphide, indium antimonide, gallium arsenic phosphide, or gallium indium phosphide), or the like. Further, the substrate 100 may include an epitaxial layer (epi-layer), which may be strained for performance enhancement, and/or may include a silicon-on-insulator (SOI) structure.

Referring back to FIG. 1A, the method M1 then proceeds to block S102 where a stack is formed on the substrate. With reference to FIGS. 2A and 2B, in some embodiments of block S102, a stack 104 including a first multi-layer stack 106, a middle sacrificial layer 108 and a second multi-layer stack 110 is formed over the substrate 100. The first multi-layer stack 106 includes alternating stacked first sacrificial layers 112 and first semiconductor layers 114. The middle sacrificial layer 108 is formed between the first multi-layer stack 106 and the second multi-layer stack 110. The second multi-layer stack 110 includes alternating stacked second sacrificial layers 116 and second semiconductor layers 118. In some embodiments, as will be subsequently described in greater detail, the first sacrificial layers 112, the middle sacrificial layer 108 and the second sacrificial layers 116 will be removed in sequence as shown in FIGS. 23B, 26B and 28B.

The first sacrificial layers 112 have a high etch selectivity with respect to the first semiconductor layers 114 during a subsequent etch process. An etch selectivity describes an etch ratio between two different materials being etched. The second sacrificial layers 116 have a high etch selectivity with respect to the second semiconductor layers 118 during a subsequent etch process. In some embodiments, the first semiconductor layers 114 include a material different from a material of the first sacrificial layers 112. The second semiconductor layers 118 include a material different from a material of the second sacrificial layers 116. The first sacrificial layers 112, the second sacrificial layers 116 and the middle sacrificial layer 108 may include materials different from one another. The first semiconductor layers 114 and the second semiconductor layers 118 may each be selected from the candidate semiconductor materials of the substrate 100. For example, the first semiconductor layers 114 and the second semiconductor layers 118 may include Si, Ge, Sn, Si₁₋ₓGeₓ, Ge_{1-y}Sn_{y}, Si_{1-x-y}GeₓSn_{y}, III-V compound semiconductor, or the like. In some embodiments, the first semiconductor layers 114 and the second semiconductor layers 118 include the same material, such as Ge.

In some embodiments, the first sacrificial layers 112, the second sacrificial layers 116 and the middle sacrificial layer 108 include silicon germanium with germanium atomic percentage different from one another. In some embodiments, the first semiconductor layers 114 may include germanium, and the first sacrificial layers 112 may include silicon germanium, for example, SiₓGe₁₋ₓ, where x can be in the range of 0 to 1. In some embodiments, the first sacrificial layers 112 include Si_{0.2}Ge_{0.8}. In some embodiments, the second semiconductor layers 118 may include germanium, and the second sacrificial layers 116 may include silicon germanium, for example, SiₓGe₁₋ₓ, where x can be in the range of 0 to 1. In some embodiments, the second sacrificial layers 116 include Si_{0.6}Ge_{0.4}. In some embodiments, the middle sacrificial layer may include silicon germanium, such as Si_{0.4}Ge_{0.6}.

In some embodiments, the first multi-layer stack 106 includes three layers of the first sacrificial layers 112 and two layers of the first semiconductor layers 114. In some embodiments, the second multi-layer stack 110 includes three layers of the second sacrificial layers 116 and two layers of the second semiconductor layers 118. It should be appreciated that the first multi-layer stack 106 may include any number of the first sacrificial layers 112 and the first semiconductor layer 114, and the second multi-layer stack 110 may include any number of the second sacrificial layers 116 and the second semiconductor layer 118. By way of example but not limiting the present disclosure, a number of the first semiconductor layers 114 and the second semiconductor layers 118 may be in a range from about 1 to about 500.

In some embodiments, each of the layers of the stack 104 may be grown by a process such as vapor phase epitaxy (VPE) or molecular beam epitaxy (MBE), deposited by a process such as chemical vapor deposition (CVD) or atomic layer deposition (ALD), or the like. Subsequently, the stack 104 is patterned by using suitable photolithography and etching techniques, resulting in a fin-like stack.

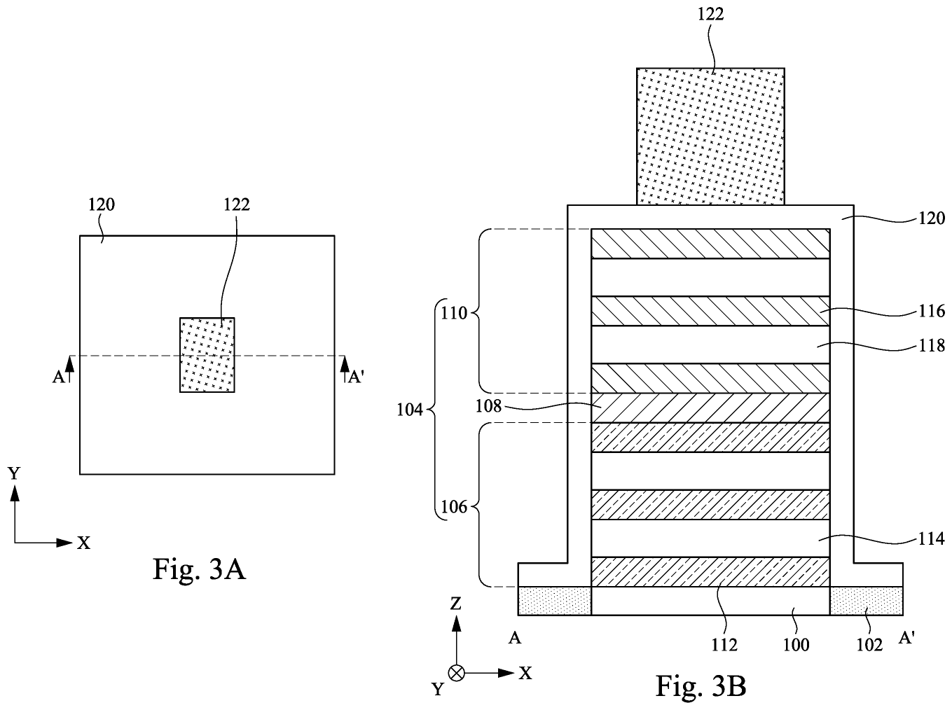

Referring back to FIG. 1A, the method 1000 then proceeds to block S104 where a dielectric layer is deposited over the substrate. With reference to FIGS. 3A and 3B, in some embodiments of block S104, a dielectric layer 120 is deposited over the substrate 100. The dielectric layer 120 extends along sidewalls and a top surface of the stack 104 and a top surface of the STI region 102. The dielectric layer 120 is then etched using acceptable photolithography techniques, exposing the STI region 102. In some embodiments, the dielectric layer 120 may be made of silicon oxide. In some other embodiments, the dielectric layer 120 includes silicon nitride, silicon oxynitride, silicon carbide, SiOC, tetraethoxysilane (TEOS), phosphosilicate glass (PSG), borophosphosilicate glass (BPSG), low-k dielectric material, or the like. Examples of low-k dielectric material include, but are not limited to, fluorinated silica glass (FSG), carbon doped silicon oxide, amorphous fluorinated carbon, parylene, bis-benzocyclobutenes (BCB), or polyimide. In some embodiments, the dielectric layer 120 may be deposited using any suitable deposition method, such as CVD, physical vapor deposition (PVD), ALD, PEALD, PECVD, SACVD, FCVD, spin-on, or the like. In some embodiments, the dielectric layer 120 may include the material similar to the material of the STI region 102. For example, the dielectric layer 120 and the STI region 102 both include SiO₂.

Referring back to FIG. 1A, the method 1000 then proceeds to block S106 where a dummy gate structure is deposited over the dielectric layer. With reference to FIGS. 3A and 3B, in some embodiments of block S106, a dummy gate structure 122 is formed on the dielectric layer 120 over the stack 104. Formation of the dummy gate structure 122 includes depositing a dummy gate material across the stack 104, followed by patterning the dummy gate material. The dummy gate material can be any acceptable electrode layer, such as polysilicon, metal, or the like. The dummy gate material can be deposited by any acceptable deposition process, such as CVD, plasma enhanced CVD (PECVD), or the like. In some embodiments, the dummy gate material is patterned by using a patterned photoresist as an etch mask. The patterned photoresist can be a photoresist layer (not shown) or other masks (not shown) formed over the dummy gate material formed by a spin-on technique and then patterned using acceptable photolithography techniques.

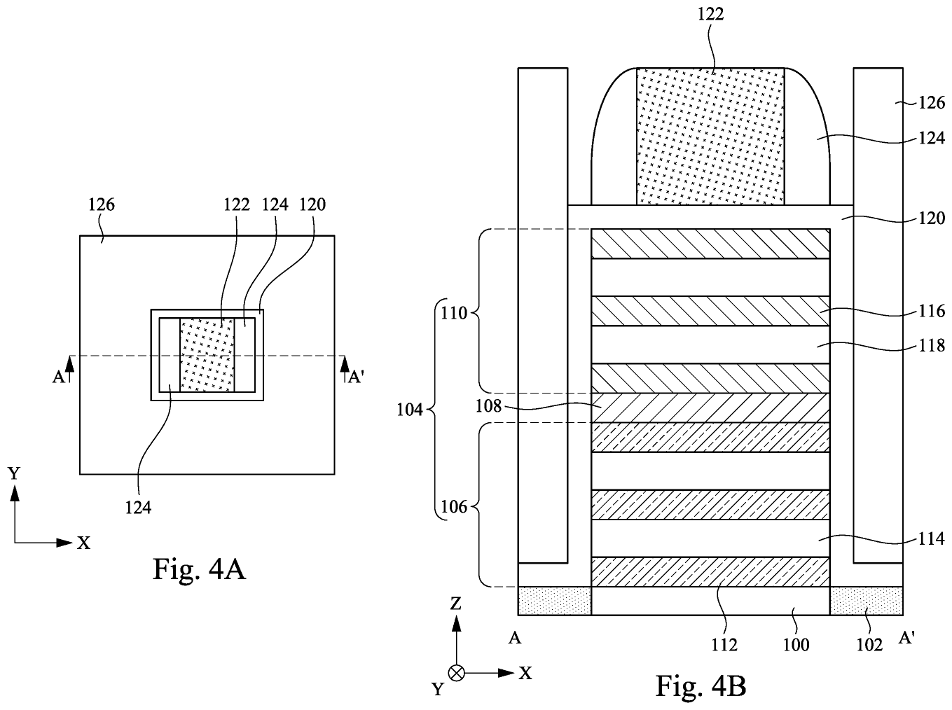

Referring to FIGS. 4A and 4B, gate spacers 124 are formed on sidewalls of the dummy gate structure 122. In some embodiments of the gate spacer formation step, a spacer material may be conformally deposited on the dielectric layer 120 and then be subsequently etched back to form gate spacers 124. The spacer material is made of a low-k dielectric material. The low-k dielectric material has a dielectric constant (k value) lower than about 3.5. Suitable materials for the low-k dielectric material may include silicon oxide, silicon nitride (e.g., Si₃N₄), silicon oxynitride, or the like. By way of example and not limitation, the spacer material may be formed by a suitable process, such as a deposition process. For example, the deposition process includes a chemical vapor deposition (CVD) process or a physical vapor deposition (PVD) process. An anisotropic etching process, such as plasma etch, is then performed to the deposited spacer material to expose portions of the dielectric layer 120 not covered by the dummy gate structure 122. A portion of the spacer material on a top surface of the dummy gate structure 122 may be completely removed by this anisotropic etching process. A portion of the spacer material on sidewalls of the dummy gate structure 122 may remain, forming gate spacers 124.

Afterwards, a patterned photoresist 126 or other masks may be formed on the dielectric layer 120. In some embodiments, the patterned photoresist 126 may be formed by a spin-coating technique and can then be patterned using acceptable photolithography techniques. The dummy gate structure 122, the gate spacers 124 and a portion of the dielectric layer 120 is exposed by openings in the patterned photoresist 126.

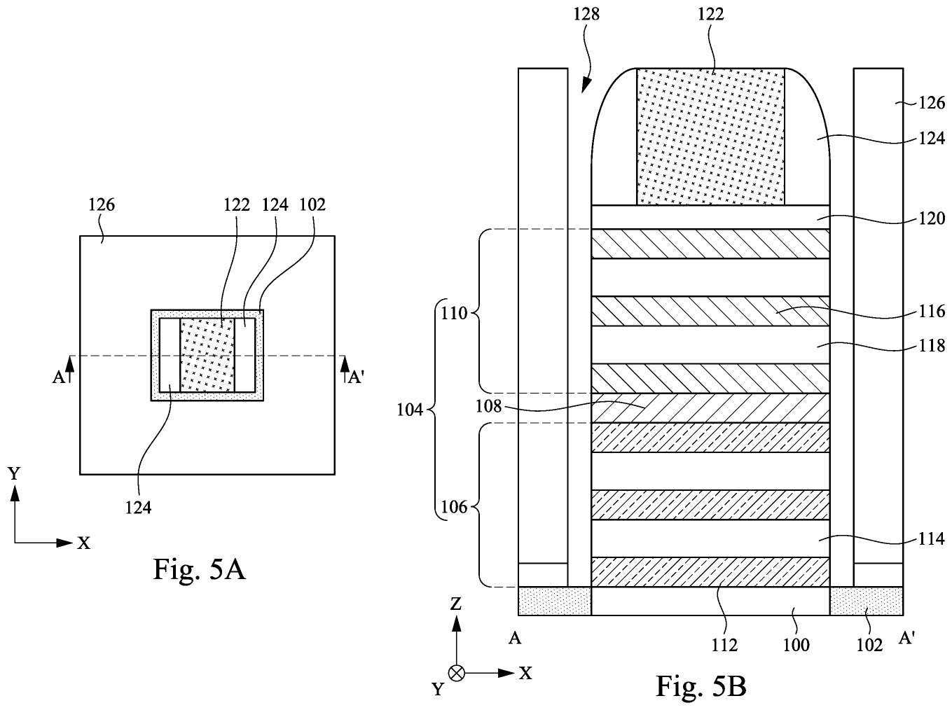

Referring back to FIG. 1A, the method 1000 then proceeds to block S108 where the dielectric layer 120 is etched. With Reference to FIGS. 5A and 5B, in some embodiments of block S108, the dielectric layer 120 is not covered by the patterned photoresist 126, the dummy gate structure 122 and the gate spacers 124 are etched by an etching process, forming trenches 128. The trenches 128 in the top view of FIG. 5A are connected to form a rectangular ring-shaped pattern.

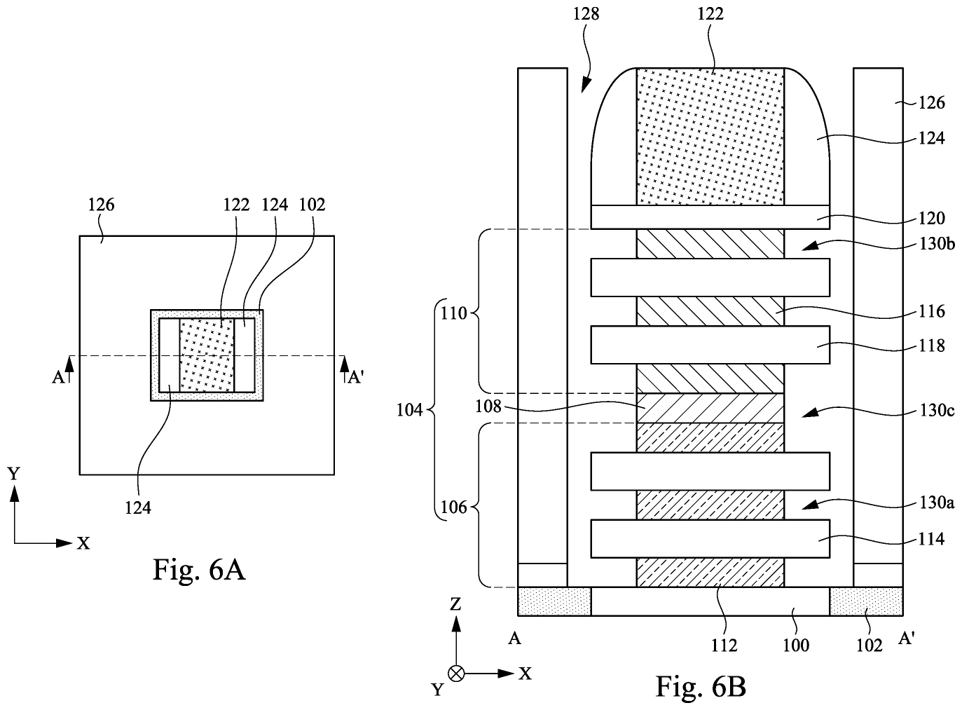

Referring back to FIG. 1A, the method 1000 then proceeds to block S110 where sidewalls of the first sacrificial layers, the second sacrificial layers and the middle sacrificial layer are etched. With reference to FIGS. 6A and 6B, in some embodiments of block S110, sidewalls of the first sacrificial layers 112, the second sacrificial layers 116 and the middle sacrificial layer 108 exposed by the trenches 128 are etched to form sidewall recesses 130a between corresponding first semiconductor layers 114, sidewall recesses 130b between a topmost one of the first semiconductor layers 114 and a bottommost one of the second semiconductor layers 118, and sidewall recesses 130c between corresponding second semiconductor layers 118. Although sidewalls of the first sacrificial layers 112, the second sacrificial layers 116 and the middle sacrificial layer 108 in the sidewall recesses 130a, 130b, 130c are illustrated as being straight in FIG. 6B, the sidewalls may be concave or convex in some other embodiments. The sidewalls may be etched using isotropic etching processes, such as wet etching or the like. In some embodiments in which the first sacrificial layers 112, the second sacrificial layers 116 and the middle sacrificial layer 108 include, for example, Si₁₋ₓGeₓ alloys, and the first semiconductor layers 114 and the second semiconductor layers 118 include, for example, Ge, the sidewalls can be removed by a selective wet etch or a selective dry etch process, resulting in the sidewall recesses 130a, 130b, 130c. In some embodiments, a solution of NH₄OH:H₂O₂:H₂O may be used as a selective wet etch for Si₁₋ₓGeₓ alloys, as may be used for the first sacrificial layers 112, the second sacrificial layers 116 and the middle sacrificial layer 108. In other examples, a selective dry etch includes a selective reactive ion etch using SF₆:O₂ or CF₄:O₂ etch chemistries, which is also an effective etch for Si₁₋ₓGeₓ alloys. Other suitable techniques, such as an inductively coupled plasma (ICP) etching technique, may also be used to remove the sidewalls of the first sacrificial layers 112, the second sacrificial layers 116 and the middle sacrificial layer 108.

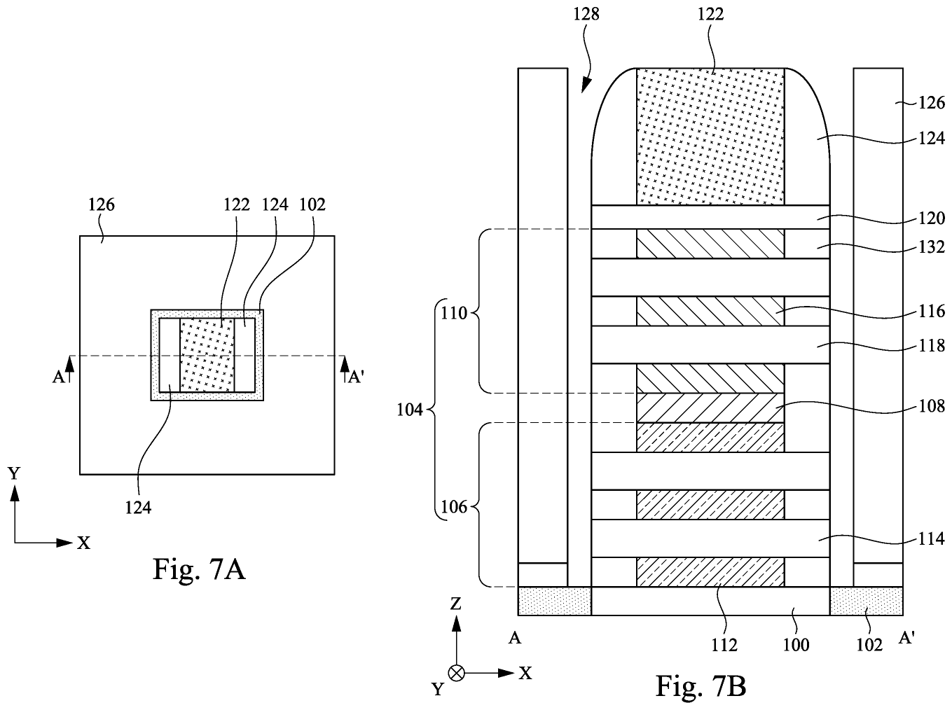

In FIGS. 7A-7B, inner spacers 132 are formed in the sidewall recesses 130a, 130b, 130c. The inner spacers 132 may be formed by depositing an inner spacer layer (not separately illustrated) over the structures illustrated in FIGS. 6A and 6B. The inner spacers 132 act as isolation features between subsequently formed epitaxial source/drain regions and gate structures. As will be discussed in greater detail below, epitaxial source/drain regions will be formed in the trenches 128, and the first sacrificial layers 112, the second sacrificial layers 116 and the middle sacrificial layer 108 will be replaced with corresponding gate structures.

The inner spacer layer may be deposited by a conformal deposition process, such as CVD, ALD, or the like. The inner spacer layer may include a material such as silicon nitride (Si₃N₄) or silicon oxynitride, although any suitable material, such as low-dielectric constant (low-k) materials having a k-value less than about 3.5, may be utilized. The inner spacer layer may then be anisotropically etched to form the inner spacers 132, such as RIE, NBE, or the like. Although outer sidewalls of the inner spacers 132 are illustrated as being flush with sidewalls of the first semiconductor layers 114 and the second semiconductor layers 118, the outer sidewalls of the inner spacers 132 may extend beyond or be recessed from sidewalls of the first semiconductor layers 114 and the second semiconductor layers 118. Moreover, although the outer sidewalls of the inner spacers 132 are illustrated as being straight in FIG. 7B, the outer sidewalls of the inner spacers 132 may be concave or convex in some other embodiments. The patterned photoresist 126 may then be removed, such as by acceptable ashing process.

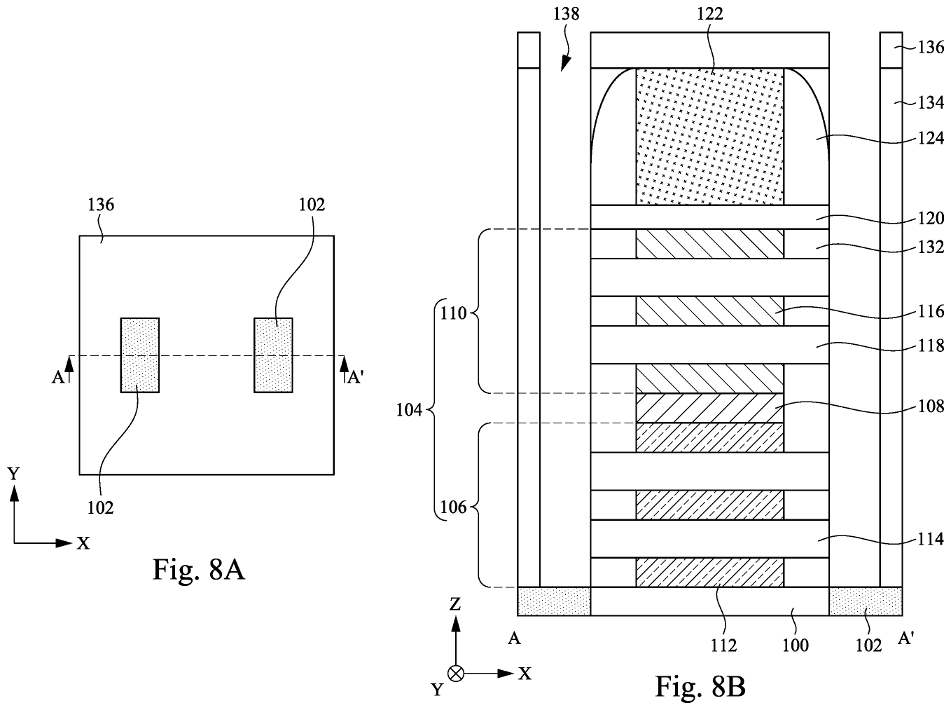

Referring back to FIG. 1A, the method 1000 then proceeds to block S112 where a dielectric layer is formed on the STI region, the dummy gate structure and the gate spacers and then patterned. With reference of FIGS. 8A and 8B, in some embodiments of block S112, a dielectric layer 134 including, for example, silicon oxide, silicon nitride, silicon oxynitride, fluoride-doped silicate glass (FSG), SiOC, or a low-k dielectric material, is formed on the STI region 102, the gate spacers 124 and the dummy gate structure 122. In some embodiments, the dielectric layer 134 may be deposited using a flowable chemical vapor deposition (FCVD), low pressure chemical vapor deposition (LPCVD), plasma enhanced chemical vapor deposition (PECVD), chemical vapor deposition (CVD) or the like. A photoresist 136 or other masks (not shown) can then be formed over the dielectric layer 134 using a spin-on technique and can then be patterned using acceptable photolithography techniques, form openings in the photoresist 136, exposing the dielectric layer 134. Then, the dielectric layer 134 is patterned through the openings in the photoresist 136 by an etch process such that the STI region 102 is exposed, forming trenches 138. After etching the dielectric layer 134, the photoresist 136 may be removed, such as by an acceptable ashing process.

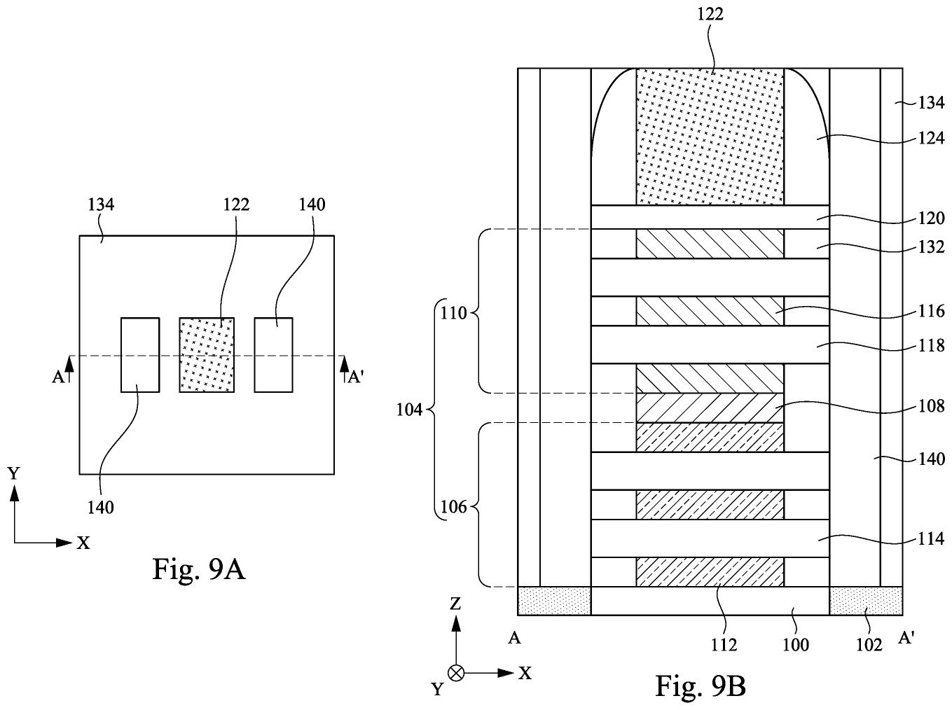

Referring back to FIG. 1B, the method 1000 then proceeds to block S114 where an epitaxial source/drain material fills into the trenches. With reference to FIGS. 9A and 9B, in some embodiments of block S114, an epitaxial source/drain material 140 is deposited into the trenches 138 (see FIG. 8B). In other words, the epitaxial source/drain material 140 is deposited on a first sidewall and a second sidewall of the stack 104. For example, formation of the epitaxial source/drain material 140 includes depositing the epitaxial source/drain material 140 to overfill the trenches 138, followed by a chemical mechanical planarization (CMP) process to planarize the epitaxial source/drain material 140 such that the top surfaces of the dielectric layer 134 and the dummy gate structure 122 are exposed.

The epitaxial source/drain material 140 may be epitaxially grown by a selective epitaxy growth using exposed end surfaces of the first and second semiconductor layers 114 and 118 as epitaxy seed layers. The epitaxial source/drain material 140 may be grown by a process such as vapor phase epitaxy (VPE) or molecular beam epitaxy (MBE), liquid phase epitaxy (LPE), and/or other suitable processes. The epitaxial source/drain material 140 may be implanted with dopants to form source/drain regions, followed by an anneal. In some embodiments, the epitaxial source/drain material 140 may be in situ doped during growth. In some embodiments, the epitaxial source/drain material 140 may include any acceptable material appropriate for n-type transistors. For example, if the first semiconductor layers 114 and the second semiconductor layers 118 are Ge, the epitaxial source/drain material 140 may include materials exerting a tensile strain on the first semiconductor layers 114 and the second semiconductor layers 118, such as silicon doped with n-type dopants, to boost electron mobility. For example, the epitaxial source/drain material 140 is phosphorous doped silicon or arsenic doped silicon.

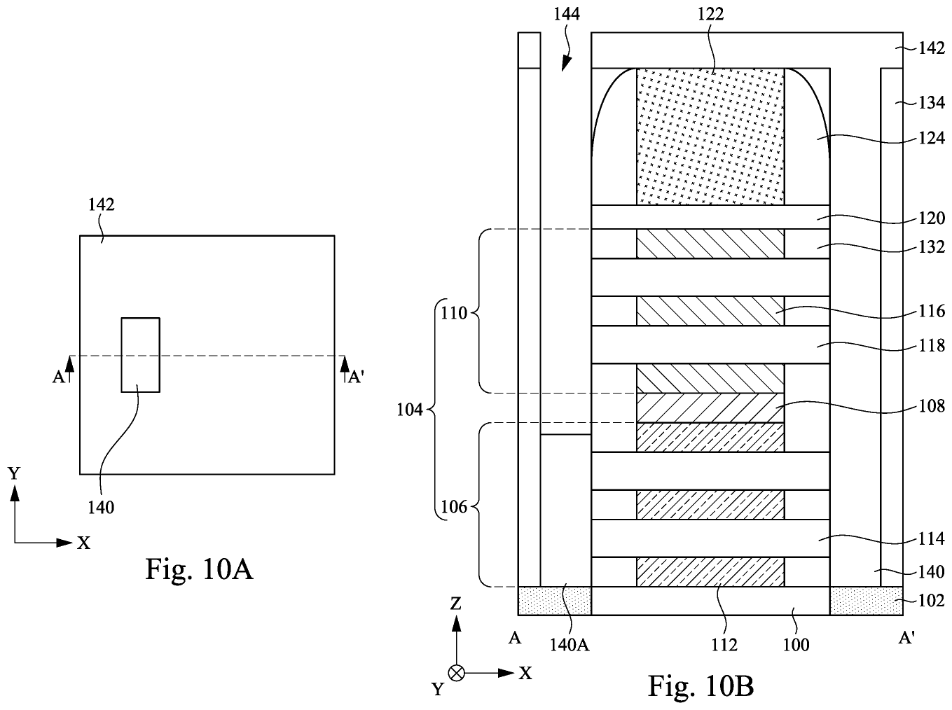

Referring back to FIG. 1B, the method 1000 then proceeds to block S116 where a first portion of the epitaxial source/drain material is recessed. With reference to FIGS. 10A and 10B, in some embodiments of block S116. An etching process is performed to recess a first portion of the epitaxial source/drain material 140 which is on the first sidewall of the stack 104, resulting in an epitaxial source/drain region 140A. This may be accomplished by a photolithography patterning process using a patterned photoresist 142. For example, the patterned photoresist 142 can be a photoresist layer (not shown) or other masks (not shown) formed over the dielectric layer 134, the dummy gate structure 122 and a second portion of the epitaxial source/drain material 140 by a spin-on technique and then patterned using acceptable photolithography techniques. The patterned photoresist 142 covers the second portion of the epitaxial source/drain material 140, the dielectric layer 134 and the dummy gate structure 122. The etching process to recess the first portion of the epitaxial source/drain material 140 may be an anisotropic etching process using inductively coupled plasma (ICP) etching, reactive ion etching (RIE), and/or other suitable etching techniques. The etching process is selectively tuned to remove the epitaxial source/drain material 140 but not the patterned photoresist 142. As a result, a recess 144 is formed over a top surface of the first portion of the epitaxial source/drain material 140. The patterned photoresist 142 may then be removed, such as by acceptable etching process.

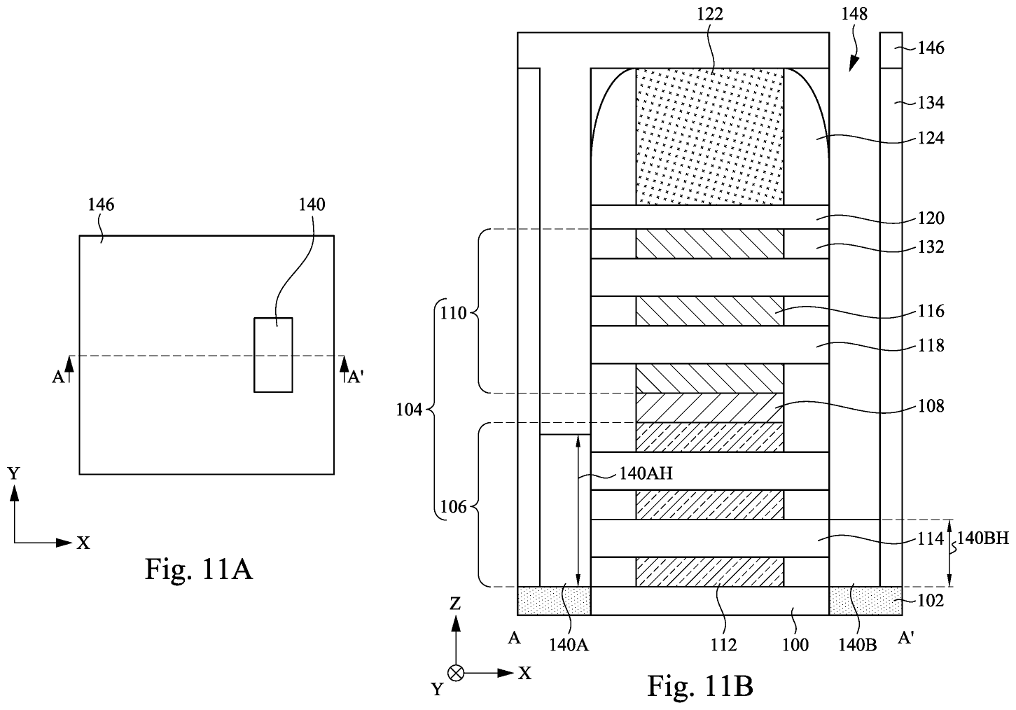

Referring back to FIG. 1B, the method 1000 then proceeds to block S118 where a second portion of the epitaxial source/drain material is recessed. With reference to FIGS. 11A and 11B, in some embodiments of block S118, an etching process is performed to recess the second portion of the epitaxial source/drain material 140 which is on the second sidewall of the stack 104, resulting in an epitaxial source/drain region 140B. In other words, the epitaxial source/drain region 140A on the second sidewall of the stack 104 is etched back such that the epitaxial source/drain region 140A on the first sidewall of the stack 104 has a height 140AH different from a height 140BH of the epitaxial source/drain region 140B on the second sidewall. For example, the height 140AH is greater than the height 140BH. The epitaxial source/drain region 140A and the epitaxial source/drain region 140B have top surfaces at different elevations. This may be accomplished by a photolithography patterning process using a patterned photoresist 146. For example, the patterned photoresist 146 can be a photoresist layer (not shown) or other masks (not shown) formed over the dielectric layer 134, the dummy gate structure 122 and the epitaxial source/drain region 140A using a spin-on technique and then patterned using acceptable photolithography techniques. The patterned photoresist 146 covers the epitaxial source/drain region 140A, the dielectric layer 134 and the dummy gate structure 122. The etching process to recess the second portion of the epitaxial source/drain material 140 may be an anisotropic etching process using inductively coupled plasma (ICP) etching, reactive ion etching (RIE), and/or other suitable etching techniques. The etching process is selectively tuned to remove the epitaxial source/drain material 140 but not the patterned photoresist 146. As a result, a recess 148 is formed over a top surface of the second portion of the epitaxial source/drain material 140. The patterned photoresist 146 may then be removed, such as by acceptable ashing process.

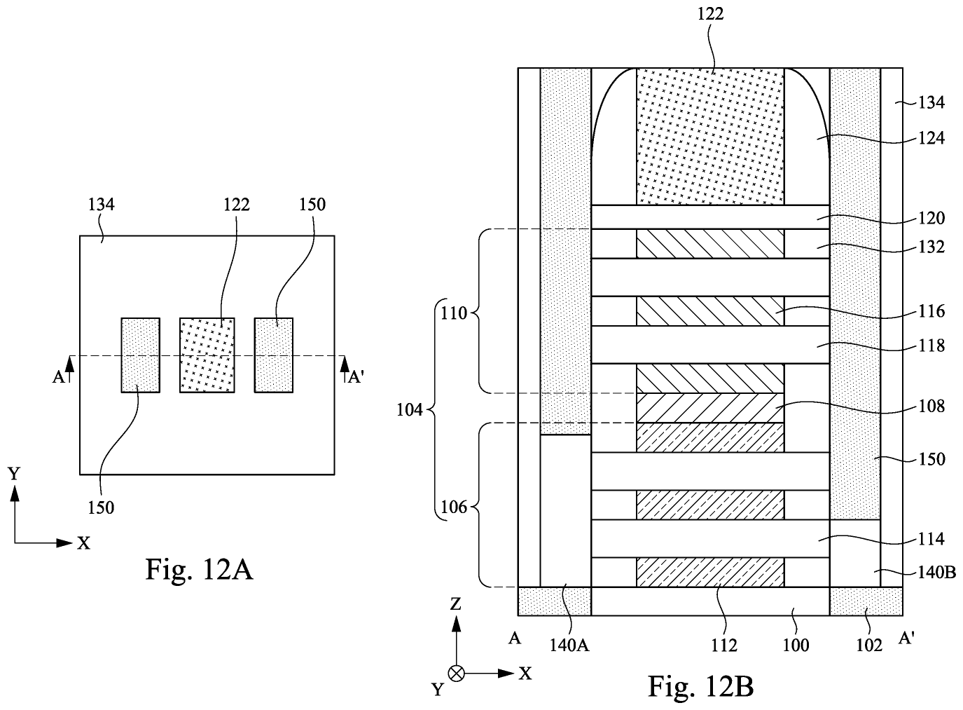

Referring back to FIG. 1B, the method 1000 then proceeds to block S120 where an isolation material fills into the recesses. With reference to FIGS. 12A and 12B, in some embodiments of block S120, an isolation material 150 is formed in the recess 144 and the recess 148. Formation of the isolation material 150 includes depositing the isolation material 150 to overfill the recesses 144, 148, followed by a chemical mechanical planarization (CMP) process to planarize the isolation material such that the top surfaces of the dielectric layer 134 and the dummy gate structure 122 are exposed. For example, the isolation material 150 may be deposited using the deposition process such as chemical vapor deposition (CVD) process or physical vapor deposition (PVD) process.

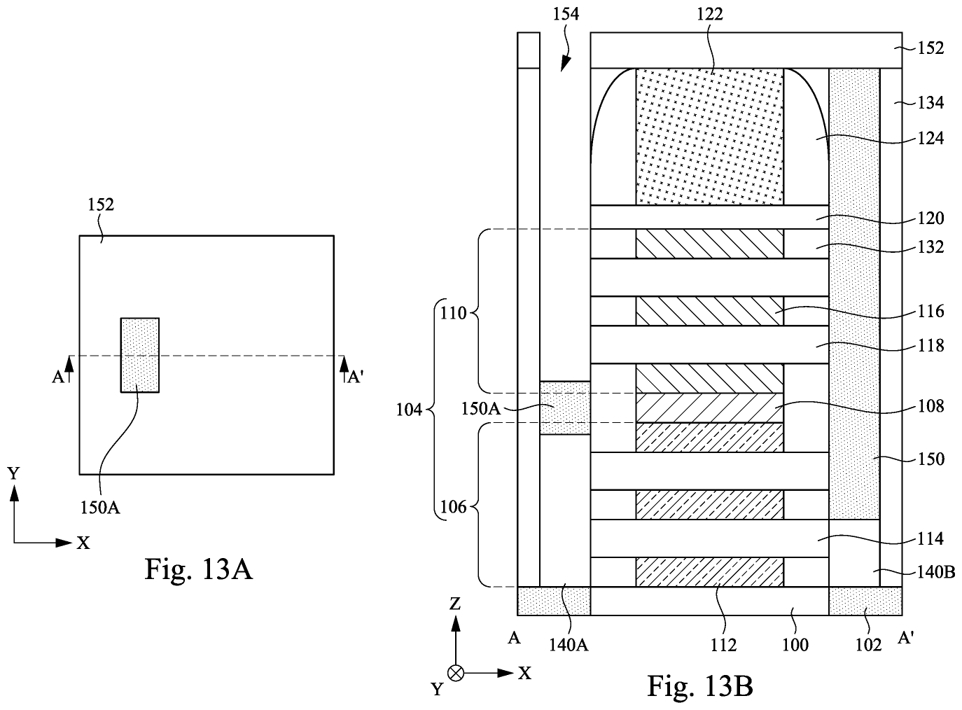

Referring back to FIG. 1B, the method 1000 then proceeds to block S122 where a first portion of the isolation material 150 is recessed. With reference to FIGS. 13A and 13B. in some embodiments of block S122, an etching process is performed to recess a first portion of the isolation material 150 which is on the first sidewall of the stack 104. The remainder of the first portion of the isolation material 150 can be referred to as a first isolation structure 150A. This may be accomplished by a photolithography patterning process using a patterned photoresist 152. For example, the patterned photoresist 152 can be a photoresist layer (not shown) or other masks (not shown) formed over the dielectric layer 134, the dummy gate structure 122 and the second portion of isolation material 150 using a spin-on technique and then patterned using acceptable photolithography techniques. The patterned photoresist 152 covers the second portion of the isolation material 150, the dielectric layer 134 and the dummy gate structure 122. The etching process to recess the first portion of the isolation material 150 may be an anisotropic etching process using inductively coupled plasma (ICP) etching, reactive ion etching (RIE), and/or other suitable etching techniques. The etching process is selectively tuned to remove the isolation material 150 but not the patterned photoresist 152. As a result, a recess 154 is formed over a top surface of the first isolation structure 150A. The patterned photoresist 152 may then be removed, such as by acceptable ashing process.

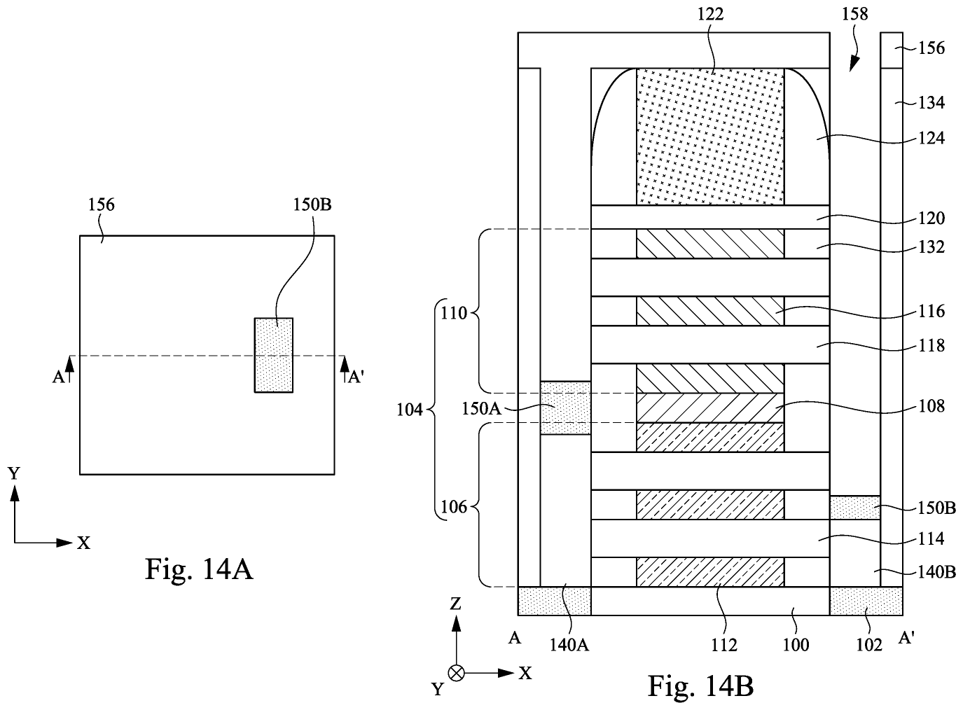

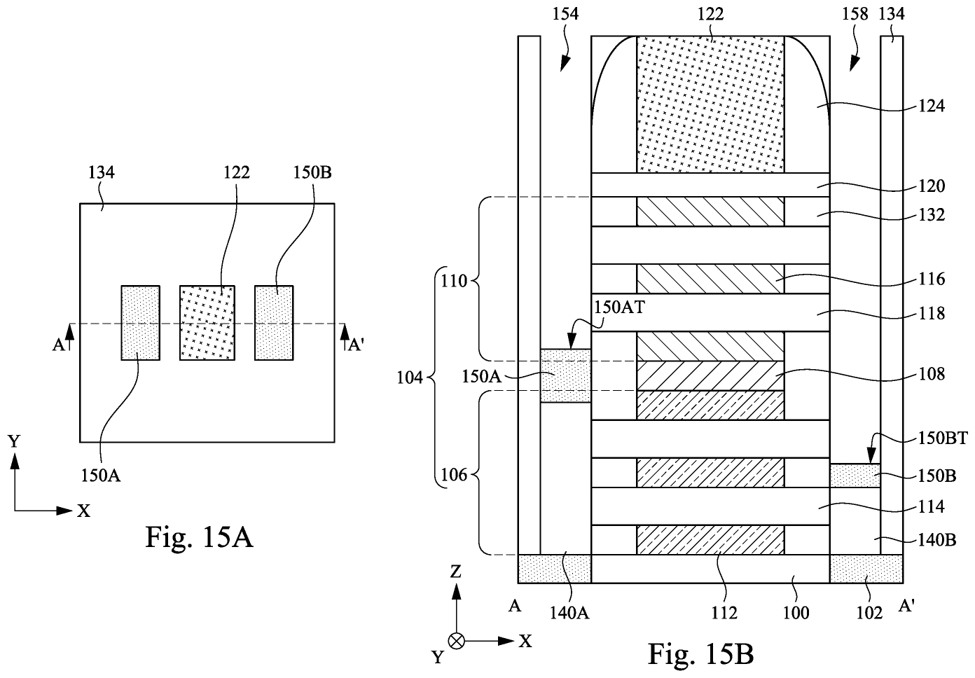

Referring back to FIG. 1B, the method 1000 then proceeds to block S124 where a second portion of the isolation material 150 is recessed. With reference to FIGS. 14A and 14B. in some embodiments of block S124, the second portion of the isolation material 150 is recessed. An etching process is performed to recess the second portion of the isolation material 150 which is on the second sidewall of the stack 104. The remainder of the second portion of the isolation material 150 can be referred to as a second isolation structure 150B. This may be accomplished by a photolithography patterning process using a patterned photoresist 156. For example, the patterned photoresist 156 can be a photoresist layer (not shown) or other masks (not shown) formed over the dielectric layer 134, the dummy gate structure 122 and the first isolation structure 150A using a spin-on technique and then patterned using acceptable photolithography techniques. The patterned photoresist 156 covers the first isolation structure 150A, the dielectric layer 134 and the dummy gate structure 122. The etching process to recess the second portion of the isolation material 150 may be an anisotropic etching process using inductively coupled plasma (ICP) etching, reactive ion etching (RIE), and/or other suitable etching techniques. The etching process is selectively tuned to remove the isolation material 150 but not the patterned photoresist 156. As a result, a recess 158 is formed over a top surface of the second isolation structure 150B. The patterned photoresist 156 may then be removed, such as by acceptable etching process. The resulting structure is shown in FIGS. 15A and 15B. The first isolation structure 150A and the second isolation structure 150B have top surfaces at different elevations. The second isolation structure has a top surface 150BT lower than a top surface 150AT of the first isolation structure 150A.

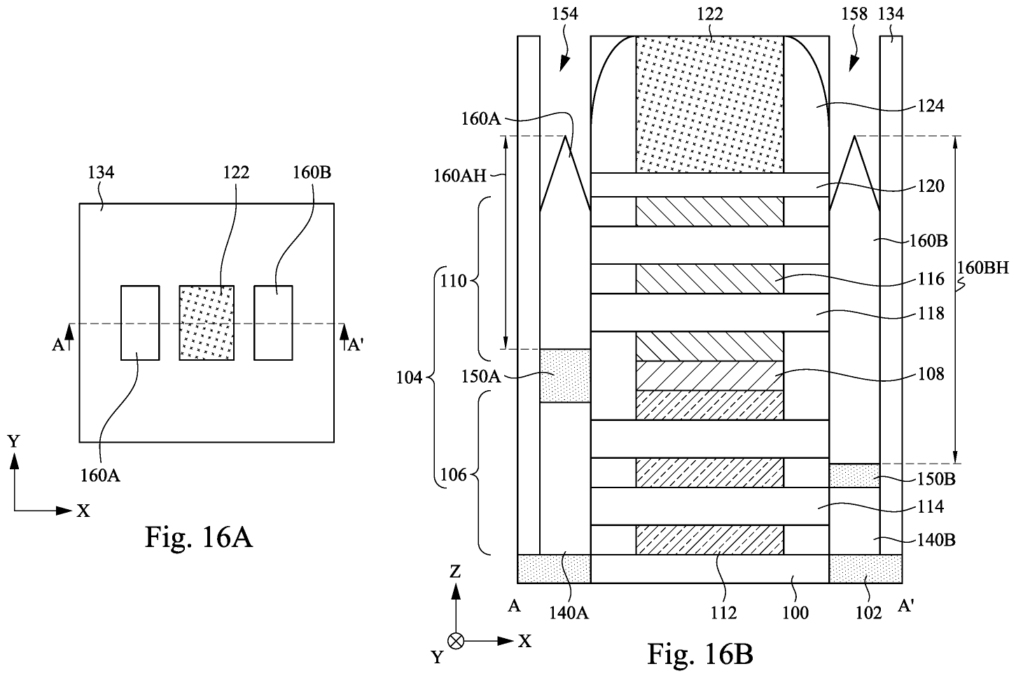

Referring back to FIG. 1B, the method 1000 then proceeds to block S126 where epitaxial source/drain materials are formed on the first isolation structure and the second isolation structure. Reference is made to FIGS. 16A and 16B. An epitaxial source/drain region 160A and an epitaxial source/drain region 160B are formed on the first isolation structure 150A and the second isolation structure 150B, respectively. The epitaxial source/drain region 160A has a height 160AH different from a height 160BH of the epitaxial source/drain region 160B. For example, the height 160AH is less than the height 160BH. The epitaxial source/drain region 160A and the epitaxial source/drain region 160B have bottom surfaces at different elevations. The epitaxial source/drain region 160B interfaces a sidewall of a top one of the first semiconductor layers 114. The epitaxial source/drain regions 160A and 160B may be formed by selective epitaxy growth by using ends surfaces of the second semiconductor layers 118 and the first semiconductor layers 114 as epitaxy seed layers. Formation of the epitaxial source/drain regions 160A, 160B may be performed by using vapor phase epitaxy (VPE) or molecular beam epitaxy (MBE), liquid phase epitaxy (LPE), and/or other suitable processes.

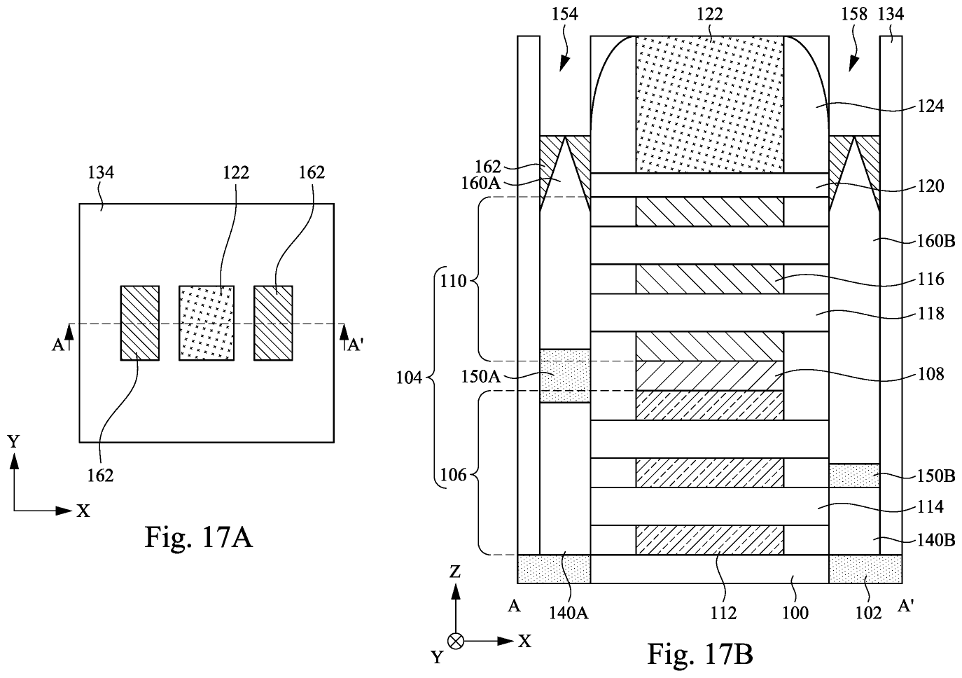

Referring back to FIG. 1C, the method 1000 then proceeds to block S128 where source/drain contacts are formed on the epitaxial source/drain materials. With reference to FIGS. 17A and 17B, in some embodiments of block S128, source/drain contacts 162 are formed on the epitaxial source/drain regions 160A, 160B. Formation of the source/drain contacts 162 includes depositing the source/drain contact 162 to overfill the recesses 154 and 158 by a blanket deposition using an ALD process, a CVD process, a PVD process, followed by a chemical mechanical planarization (CMP) process to planarize the source/drain contacts 162 such that the top surfaces of the dielectric layer 134 and the dummy gate structure 122 are exposed and an etching back process to lower a top surface of the source/drain contacts 162. The etching back process may be an anisotropic etching process using inductively coupled plasma (ICP) etching, reactive ion etching (RIE), and/or other suitable etching techniques. In some embodiments, the source/drain contacts 162 can be made of metal such as, for example, cobalt (Co), tungsten (W), copper (Cu), nickel (Ni), ruthenium (Ru), or other suitable materials.

Referring back to FIG. 1C, the method 1000 then proceeds to block S130 where the dielectric layer is removed. With reference to FIGS. 18A-18C, in some embodiments of FIGS. 18A-18C, the dielectric layer 134 is removed by a suitable etching process. For example, the dielectric layer 134 is removed by an isotropic etching process such as a wet etch process using a suitable etch chemistry. In such embodiments, the etchants and other etching parameters may be tuned so that a certain material of the dielectric layer 134 is etched without etching other materials such as the dummy gate structure 122 and the gate spacers 124. In other words, a wet, isotropic etch selective to the material of the dielectric layer 134 is used.

Referring back to FIG. 1C, the method 1000 then proceeds to block S132 where the dummy gate structure and the dielectric layer are removed, and then a dielectric layer is deposited on the stack and the STI region. With reference to FIGS. 19A-19C, in some embodiments of block S132, the dummy gate structure 122 and the dielectric layer 120 (see FIG. 18C) are removed. A dielectric layer 164 is formed on the stack 104 and the STI region 102. For example, formation of the dielectric layer 164 includes depositing the dielectric layer 164 covering the source/drain contacts 162, followed by a chemical mechanical planarization (CMP) process to planarize the dielectric layer 164 to obtain the dielectric layer 164 with a desired thickness. In some embodiments, after planarizing the dielectric layer 164, the dielectric layer 164 covers the source/drain contacts 162 to protect the source/drain contacts 162 from being damaged or oxidized by subsequent processes. In some embodiments, the dielectric layer 164 is made of a low-k dielectric material. The low-k dielectric material has a dielectric constant (k value) of lower than about 3.5. Suitable materials for the low-k dielectric material may include SiOC, silicon oxide, silicon nitride, silicon oxynitride, or the like. By way of example and not limitation, the dielectric material may be formed using processes such as, CVD process, a subatmospheric CVD (SACVD) process, a flowable CVD process, an ALD process, a physical vapor deposition (PVD) process, or other suitable process.

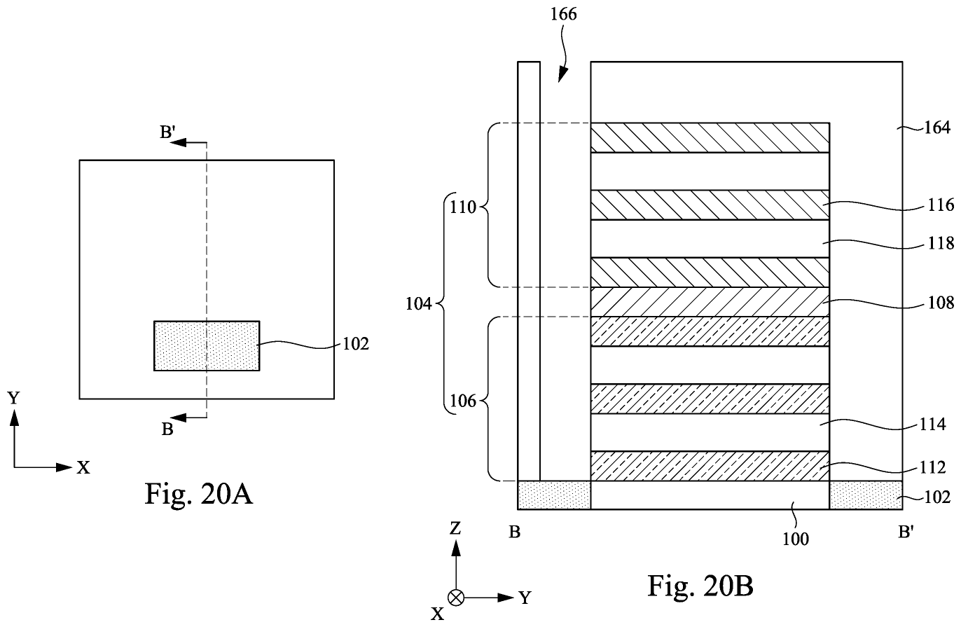

Referring back to FIG. 1C, the method 1000 then proceeds to block S134 where the dielectric layer is patterned. With reference to FIGS. 20A and 20B, in some embodiments of block S134, the dielectric layer 164 is patterned, forming a first trench 166 extending through the dielectric layer 164 to expose the first sidewall of the stack 104. For example, a patterned mask (not shown) may be formed over the dielectric layer 164 by using photolithography process and then the dielectric layer 164 is etched using the patterned mask as an etch mask by a suitable etching process. The photolithography process may include photoresist (or resist) coating (e.g., spin-on coating), soft baking, mask aligning, exposure, post-exposure baking, developing the photoresist, rinsing, drying (e.g., hard baking), other suitable processes, and/or combinations thereof. The etching process includes dry etching, wet etching, and/or other etching methods (e.g., reactive ion etching). After the formation of the first trench 166, the patterned mask can be removed by a suitable technique, such as etching process. In some embodiments, the first trench 166 can be interchangeably referred to a first opening.

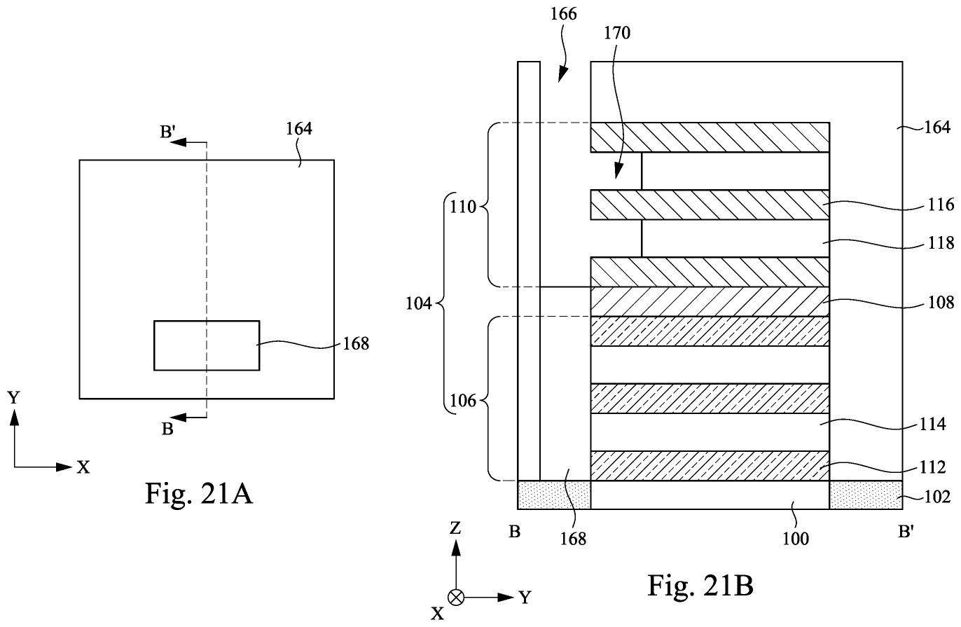

Referring back to FIG. 1C, the method 1000 then proceeds to block S136 where a protection layer is formed in the first trench and then sidewalls of the second semiconductor layers are etched. With reference to FIGS. 21A and 21B, in some embodiments of block S136, a protection layer 168 is formed in the first trench 166 to cover the first multi-layer stack 106. The protection layer 168 can protect the first multi-layer stack 106 from being etched during etching the sidewalls of the second semiconductor layers 118. In other words, during etching the sidewalls of the second semiconductor layers 118, the sidewalls of the second semiconductor layers 118 are etched without etching the first semiconductor layers 114. The sidewalls of the second semiconductor layers 118 of the second multi-layer stack 110 exposed by protection layer 168 are etched to form sidewall recesses 170 between corresponding second sacrificial layers 116. Although sidewalls of the second semiconductor layers 118 in the sidewall recesses 170 are illustrated as being straight in FIG. 21B, the sidewalls thereof may be concave or convex in some other embodiments.

The sidewalls of the second semiconductor layers 118 can be removed or etched using an etchant that selectively etches the second semiconductor layers 118 against the second sacrificial layers 116. For example, when the second semiconductor layers 118 are formed of Ge, and the second sacrificial layers 116 are formed of SiGe, the second semiconductor layers 118 can be selectively removed using a thermal etch technique using a gaseous mixture of HCl and H₂, or a dry etch technique using a plasma, such as CF₄, or a wet etch technique such as using, but not limited to, a mixture of hydrofluoric acid (HF), nitric acid (HNO₃), and acetic acid (CH₃COOH).

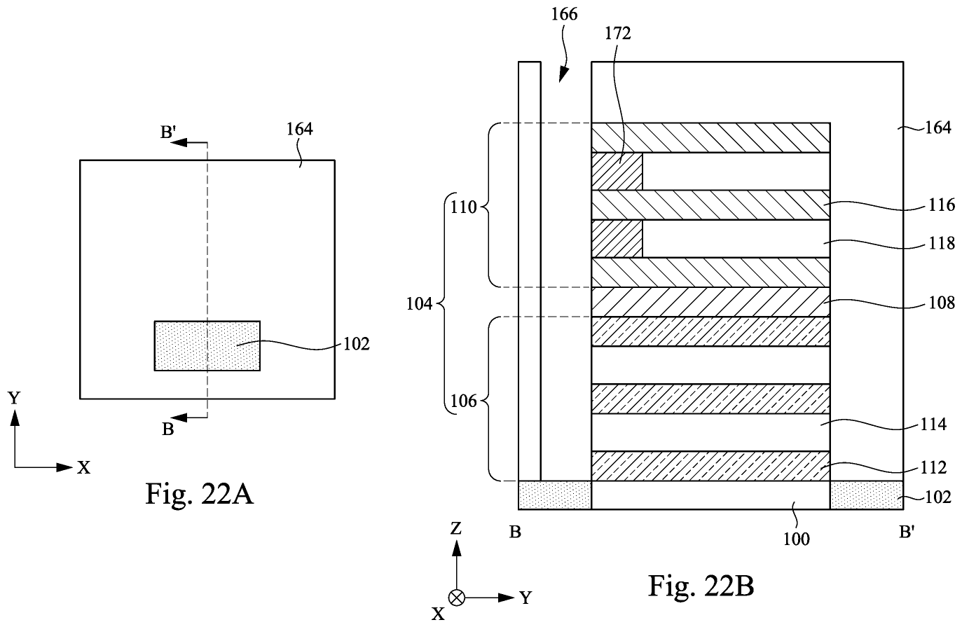

Referring back to FIG. 1C, the method 1000 then proceeds to block S138 where inner spacers are formed in the sidewall recesses. With reference to FIGS. 22A and 22B, in some embodiments of block S138, inner spacers 172 are formed in the sidewall recess 170 (see FIG. 21B). The inner spacers 172 may be formed by depositing an inner spacer layer (not separately illustrated) over the structures illustrated in FIGS. 21A and 21B. The inner spacers 172 act as isolation features between subsequently formed gate structure and the second semiconductor layers 118. As will be discussed in greater detail below, the gate structure will be formed in the first trenches 166, and the first sacrificial layers will be replaced with corresponding gate structure.

The inner spacer layer may be deposited by a conformal deposition process, such as CVD, ALD, or the like. The inner spacer layer may include a material such as SiBCN. In some embodiments, the inner spacer layer may include other low-dielectric constant (low-k) materials having a k-value less than about 3.5. The inner spacer layer may then be anisotropically etched to form the inner spacers 172, such as using RIE, NBE, or the like. Although outer sidewalls of the inner spacers 172 are illustrated as being flush with sidewalls of the second sacrificial layers 116, the outer sidewalls of the inner spacers 172 may extend beyond or be recessed from sidewalls of the second sacrificial layers 116. The protection layer 168 is then removed. In some embodiments, the protection layer 168 is removed during the etching process of anisotropically etching the inner spacer layer.

Referring back to FIG. 1C, the method 1000 then proceeds to block S140 where first sacrificial layers are removed. With reference to FIGS. 23A-23C, in some embodiments of block S140, the first sacrificial layers 112 (see FIG. 22B) in the first multi-layer stack 106 (see FIG. 22B) are removed by an isotropic etching process such as wet etching or the like using etchants which are selective to the material of the first sacrificial layers 112. Stated differently, the first sacrificial layers 112 are removed by using a selective etching process that etches the first sacrificial layers 112 at a faster etch rate than it etches the first semiconductor layers 114, thus forming spaces between the first semiconductor layers 114 (also referred to as sheet-sheet spaces if the first semiconductor layers 114 are nanosheets). The first semiconductor layers 114 are arranged one above another over the substrate 100. This step can be referred to as a channel release process. As illustrated in FIG. 23B. gaps 174 (empty spaces) are formed between the first semiconductor layers 114. At this interim processing step, the gaps 174 between the first semiconductor layers 114 may be filled with ambient environment conditions (e.g., air, nitrogen, etc).

In some embodiments, the first semiconductor layers 114 can be referred to as nanosheets, nanowires, nanoslabs, nanorings having nano-scale size (e.g., a few nanometers), depending on their geometry. For example, in some embodiments the first semiconductor layers 114 may be trimmed to have a substantial rounded shape (i.e., cylindrical) due to the selective etching process for completely removing the first sacrificial layers 112. In that case, the resultant first semiconductor layers 114 can be called nanowires. For example, the nanowires can have a diameter in a range from 0.5 nm to 50 nm. In some other embodiments, the geometry of the cross-sectional view along B-B′ line can be rectangular, square, diamond, with or without rounded corners, circular, or elliptical. In some embodiments, the first semiconductor layers 114 can have thickness substantially the same or different. For example, the first semiconductor layers 114 can have thickness in a range from 0.5 nm to 50 nm. The first semiconductor layers 114 can have a vertical distance d therebetween in a range from 3 nm to 100 nm. In some embodiments, vertical distance d between adjacent first semiconductor layers 114 can be different or substantially the same. In some other embodiments, a quantity of the first semiconductor layers 114 can be in a range from 1 to 100.

Referring back to FIG. 1D, the method 1000 then proceeds to block S142 where a first metal gate structure is formed in the first trench and the gaps. With reference to FIGS. 24A-24C, in some embodiments of block S142, a first metal gate structure 176 is formed in the first trench 166 and the gaps 174 (see FIG. 23B). The first metal gate structure 176 wraps around the first semiconductor layers 114. As the first metal gate structure 176 inherits the shape of the first sacrificial layers 112 (see FIG. 22B), it can be referred that the first sacrificial layers 112 is replaced by the first metal gate structure 176. Each of the inner spacers 172 are horizontally between the first metal gate structure 176 and a corresponding one of the second semiconductor layers 118 to space the first metal gate structure 176 apart from a corresponding one of the second semiconductor layers 118. In some embodiments, the first metal gate structure 176 includes an interfacial layer 178, a gate dielectric layer 180, a work function layer 182 and a fill metal 184. For example, the interfacial layer 178, the gate dielectric layer 180 and the work function layer 182 are blanket formed in the gaps 174 and the first trench 166 in sequence. Subsequently, the fill metal 184 is deposited over the work function layer 182, filling into a remaining space of the first trench 166. A CMP process is then performed to the interfacial layer 178, the gate dielectric layer 180, the work function layer 182 and the fill metal 184 until the dielectric layer 164 is exposed, resulting in the dielectric layer 164, the interfacial layer 178, the gate dielectric layer 180, the work function layer 182 and the fill metal 184 having substantially level top surfaces.

In some embodiments, the interfacial layer 178 is a silicon oxide layer deposited using any suitable method, such as CVD, physical vapor deposition (PVD), ALD, PEALD, PECVD, SACVD, FCVD, spin-on, or the like. In some embodiments, the gate dielectric layer 180 may include a high-k dielectric material, other suitable dielectric material, or a combination thereof. Examples of high-k dielectric material include HfO₂, HfSiO, HfSiON, HfTaO, HfTiO, HfZrO, zirconium oxide, aluminum oxide, hafnium dioxide-alumina (HfO₂—Al₂O₃) alloy, the like, or a combination thereof.

In some embodiments, the work function layer 182 includes one or more n-type work function layers which may fill into a remaining space of the gaps 174. The one or more n-type work function layers may include one or more n-type work function metals (N-metal). The n-type work function metals may exemplarily include, but are not limited to, titanium aluminide (TiAl), titanium aluminium nitride (TiAlN), carbo-nitride tantalum (TaCN), hafnium (Hf), zirconium (Zr), titanium (Ti), tantalum (Ta), aluminum (Al), metal carbides (e.g., hafnium carbide (HfC), zirconium carbide (ZrC), titanium carbide (TiC), aluminum carbide (AlC)), aluminides, and/or other suitable materials.

In some embodiments, the fill metal 184 includes a metal such as tungsten. In some other embodiments, the fill metal 184 may include, but is not limited to, titanium aluminide (TiAl), titanium aluminium nitride (TiAlN), carbo-nitride tantalum (TaCN), hafnium (Hf), zirconium (Zr), titanium (Ti), tantalum (Ta), aluminum (Al), metal carbides (e.g., hafnium carbide (HfC), zirconium carbide (ZrC), titanium carbide (TiC), aluminum carbide (AlC), aluminides, and/or other suitable materials. In alternative embodiments, the fill metal 184 may include, but is not limited to, titanium nitride (TiN), tungsten nitride (WN), ruthenium (Ru), palladium (Pd), platinum (Pt), cobalt (Co), nickel (Ni), argentum (Ag), Aurum (Au), conductive metal oxides, and/or other suitable materials. In some embodiments, the fill metal 184 may be deposited using any suitable method, such as CVD, physical vapor deposition (PVD), ALD, PEALD, PECVD, SACVD, FCVD, spin-on, or the like.

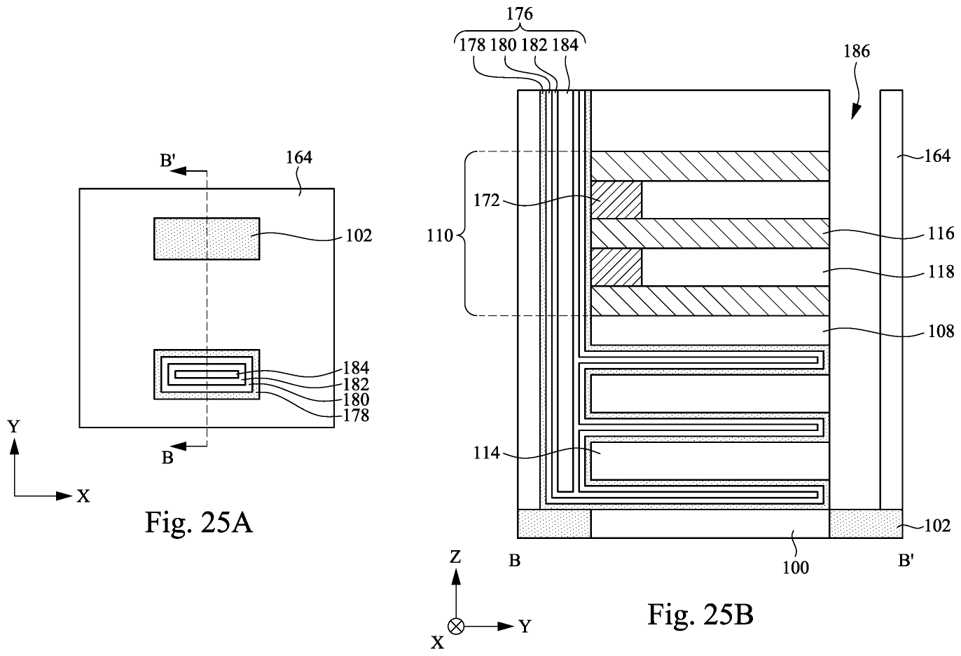

Referring back to FIG. 1D, the method 1000 then proceeds to block S144 where the dielectric layer is patterned. With reference to FIGS. 25A and 25B, in some embodiments of block S144, the dielectric layer 164 is patterned, forming a second trench 186 extending through the dielectric layer 164 to expose sidewalls of the second multi-layer stack 110, the first metal gate structure 176, the middle sacrificial layer 108 and the first semiconductor layers 114 and the top surface of the STI region 102. For example, a patterned mask (not shown) may be formed over the dielectric layer 164 by using photolithography process and then the dielectric layer 164 is etched using the patterned mask as an etch mask by a suitable etching process. The photolithography process may include photoresist (or resist) coating (e.g., spin-on coating), soft baking, mask aligning, exposure, post-exposure baking, developing the photoresist, rinsing, drying (e.g., hard baking), other suitable processes, and/or combinations thereof. The etching process includes dry etching, wet etching, and/or other etching methods (e.g., reactive ion etching). After the formation of the second trench 186, the patterned mask can be removed by a suitable technique, such as ashing process. In some embodiments, the second trench 186 can be interchangeably referred to a second opening.

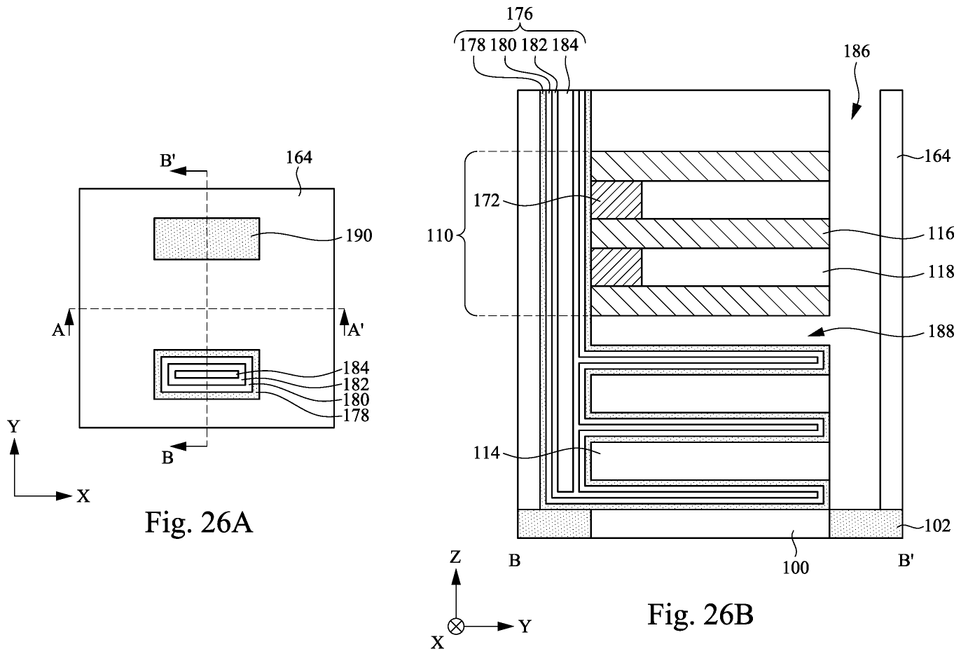

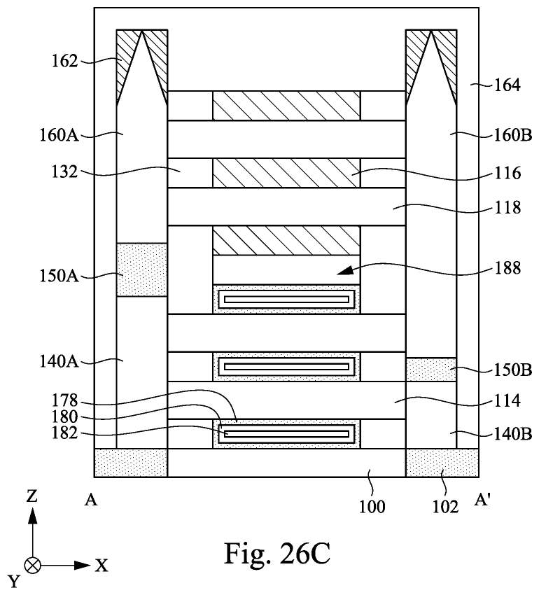

Referring back to FIG. 1D, the method 1000 then proceeds to block S146 where the middle sacrificial layer is removed. With reference to FIGS. 26A-26C, in some embodiments of block S146, the middle sacrificial layer 108 is removed using an etchant that selectively etches the middle sacrificial layer 108 against the second sacrificial layers 116, the first semiconductor layers 114 and the second semiconductor layers 118. A gap 188 is formed between the first metal gate structure and the bottommost one of the second sacrificial layers 116.

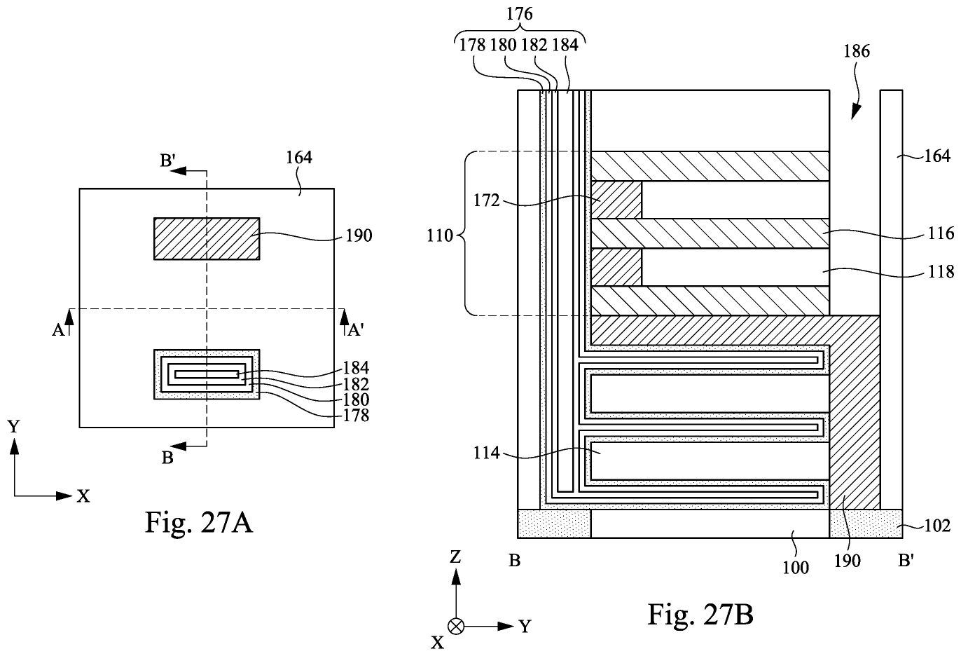

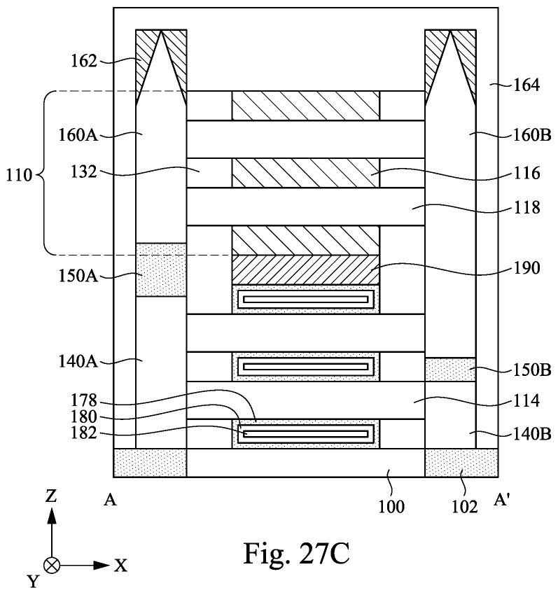

Referring back to FIG. 1D, the method 1000 then proceeds to block S148 where a spacer material is formed in the gap and the second trench. With reference to FIGS. 27A-27C, in some embodiments of block S148, a spacer material 190 is formed in the gap 188 (see FIG. 26B) and the second trench 186. In some embodiments, the inner spacers 172 have a height 172H extending along the direction perpendicular to the substrate 100 less than a maximum height 190H of the spacer material 190 extending along the direction perpendicular to the substrate 100. The spacer material 190 is wider than the inner spacers 172 in the y-axis. In some embodiments, the inner spacers 172 have a width 172W in the y-axis less than a width 190W of the spacer material 190 in the y-axis. The spacer material is a low-k dielectric layer such as a nitride layer (e.g., siliconborocarbonitride (SiBCN) layer). Formation of the spacer material includes, by way of example and not limitation, depositing the spacer material 190 to overfill the second trench 186, followed by a CMP process to planarize the spacer material 190 with the first metal gate structure 176 and the dielectric layer 164. Then, an etching process is performed to recess the spacer material 190. The etching process may be an anisotropic etch, such as RIE or dry etch. In some embodiments, the etching process is highly selective to the spacer material 190. As a result, a recess is formed over a top surface of the spacer material 190.

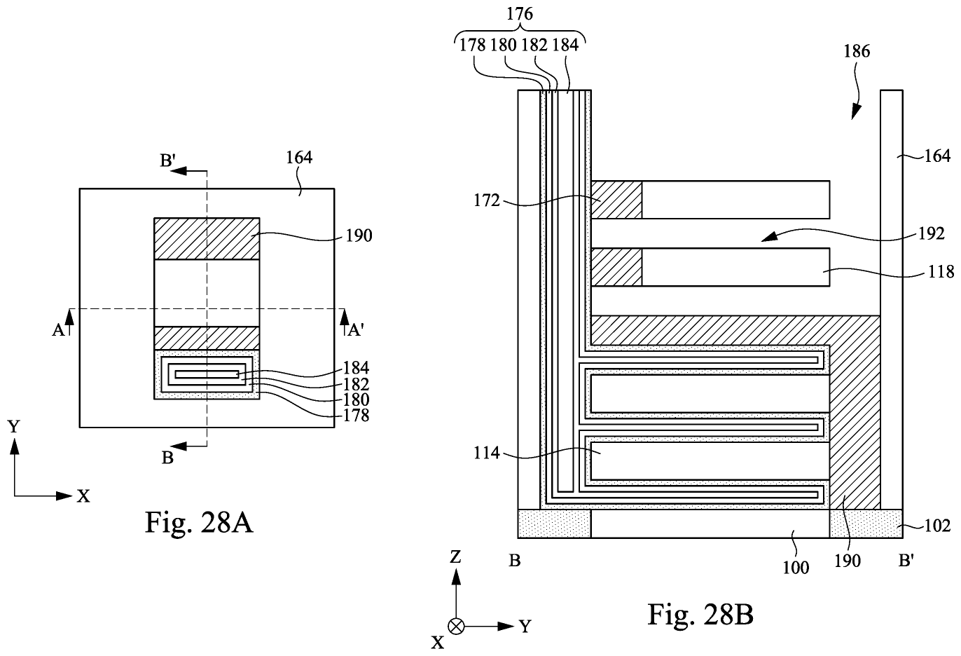

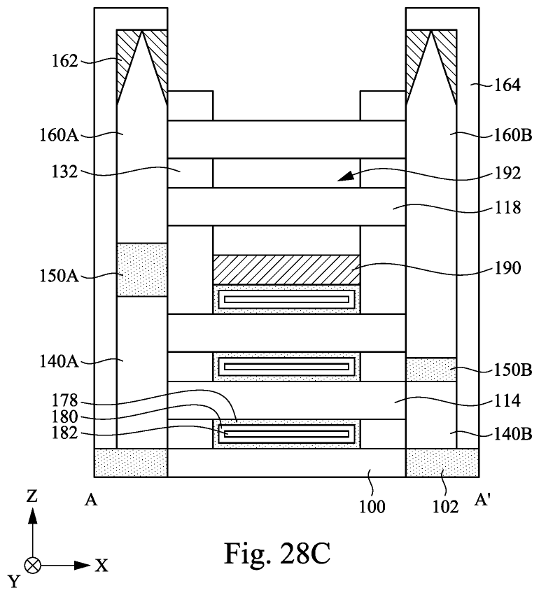

Referring back to FIG. 1D, the method 1000 then proceeds to block S150 where the second sacrificial layers are removed. With reference to FIGS. 28A-28C, in some embodiments of block S150, the dielectric layer 164 on the second multi-layer stack 110 is removed, and then the second sacrificial layers 116 (see FIG. 27B) in the second multi-layer stack 110 (see FIG. 27B) are removed. For example, the dielectric layer 164 is patterned by using suitable photolithography and etching techniques, exposing a top surface of a topmost one of the second sacrificial layers 116.

Afterwards, in some embodiments, the second sacrificial layers 116 (see FIG. 27B) can be removed by an isotropic etching process such as wet etching or the like using etchants which are selective to the material of the second sacrificial layers 116. Stated differently, the second sacrificial layers 116 are removed by using a selective etching process that etches the second sacrificial layers 116 at a faster etch rate than it etches the second semiconductor layers 118, thus forming spaces between the second semiconductor layers 118 (also referred to as sheet-sheet spaces if the second semiconductor layers 118 are nanosheets). The second semiconductor layers 118 are arranged one above another on the substrate 100. This step can be referred to as a channel release process. As illustrated in FIG. 28B, gaps 192 (empty spaces) are formed between the second semiconductor layers 118. At this interim processing step, the gaps 192 between the second semiconductor layers 118 may be filled with ambient environment conditions (e.g., air, nitrogen, etc).

In some embodiments, the second semiconductor layers 118 can be referred to as nanosheets, nanowires, nanoslabs, nanorings having nano-scale size (e.g., a few nanometers), depending on their geometry. The geometry of the second semiconductor layers 118 can be similar to the geometry of the first semiconductor layers 114, and thus the description thereof is omitted herein for clarity.

Referring back to FIG. 1D, the method 1000 then proceeds to block S152 where a second metal gate structure is formed in the second trench and the gaps. With reference to FIGS. 29A-29C, in some embodiments of block S152, a second metal gate structure 194 is formed in the second trench 186 and the gaps 192. The second metal gate structure 194 wraps around the second semiconductor layers 118. As the second metal gate structure 194 inherits the shape of the second sacrificial layers 116 (see FIG. 27B), it can be referred that the second sacrificial layers 116 is replaced by the second metal gate structure 194. The second metal gate structure 194 is spaced apart from the first metal gate structure 176. The spacer material 190 extends along sidewalls of the first semiconductor layers 114 and a bottom surface of the second metal gate structure 194, separating the first metal gate structure 176 from the second metal gate structure 194. In some embodiments, the second metal gate structure 194 includes an interfacial layer 196, a gate dielectric layer 198, a work function layer 200 and a fill metal 202. For example, the interfacial layer 196, the gate dielectric layer 198, the work function layer 200 are blanket formed in the second trench 186 and the gaps 192 in sequence. Subsequently, the fill metal 202 is deposited over the work function layer 200, filling into a remaining space of the second trench 186. A CMP is then performed on the fill metal 202 until the dielectric layer 164 and the first metal gate structure 176 are exposed, resulting in the dielectric layer 164, the interfacial layer 196, the gate dielectric layer 198, the work function layer 200, the fill metal 202 and the layers of the first metal gate structure 176 having substantially level top surfaces.

In some embodiments, the interfacial layer 196, the gate dielectric layer 198, the work function layer 200 and the fill metal 2021 may be similar to the interfacial layer 178, the gate dielectric layer 180, the work function layer 182 and the fill metal 184, respectively, in terms of composition and formation. Therefore, the description thereof is omitted herein for simplicity.

When viewed from a cross-sectional view, the first metal gate structure 176 has a height 176H, the second metal gate structure 194 has a height 194H different from the height 176H. For example, the height 194H is less than the height 176H. When viewed from a top view, the second metal gate structure 194 has a top surface area different from a top surface area of the first metal gate structure 176. For example, when viewed from the top view, the top surface area of the second metal gate structure 194 is greater than the top surface area of the first metal gate structure 176.

The source/drain contacts 162 spaced apart in a first direction (i.e., the x-axis). the first metal gate structure 176 and the second metal gate structure 194 are disposed between the source/drain contacts 162, and in a second direction (i.e., the y-axis) perpendicular to the first direction (i.e., the x-axis), the second metal gate structure 194 has a length 194L greater than a length 176L of the first metal gate structure 176. When viewed from the top view, the first metal gate structure 176 has a width 176W along the x-axis substantially the same as a width 194W of the second metal gate structure 194 along the x-axis. In some embodiments, the first semiconductor layers 114 have a width 114W along the y-axis different from a width 118W of the plurality of second semiconductor layers 118 along the y-axis. For example, the first semiconductor layers 114 have the width 114W along the y-axis greater than the width 118W of the second semiconductor layers 118 along the y-axis.

FIG. 29D is similar to FIG. 29B, except for labeling circuit reference numbers for discussing about the circuit diagram. FIG. 29E is an exemplary circuit diagram of the vertically stacked transistors in the integrated circuit of FIGS. 29A-29D in accordance with some embodiments of the present disclosure. The word “exemplary” is used herein to mean “serving as an example, instance, or illustration.” Any embodiment or design described herein as “exemplary” is not necessarily to be construed as preferred or advantageous over other embodiments or designs. Reference is made to FIGS. 29A-29E. The vertically stacked transistors include a first transistor T1, a second transistor T2, a third transistor T3 and a fourth transistor T4, collectively serving as a power amplifier (PA) 300 such as a cascode amplifier.

For example, the lower one of the first semiconductor layers 114 functions as a channel of the first transistor T1 and can be referred to as a first channel CH1, and the upper one of the first semiconductor layers 114 functions as a channel of the second transistor T2 and can be referred to as a second channel CH2. The epitaxial source/drain region 140B, which is connected to the first channel CH1, is a drain D1 of the first transistor T1 and is coupled to a high power supply voltage VDD. A lower part of the epitaxial source/drain region 140A is connected to the first channel CH1 and can thus serve as a source S1 of the first transistor T1. The source S1 and the drain D1 are on opposite sides of the first channel CH1. An upper part of the epitaxial source/drain region 140A is connected to the second channel CH2 and can thus serve as a drain D2 of the second transistor T2. The epitaxial source/drain region 160B, which is connected to the second channel CH2, is a source S2 of the second transistor T2. The source S2 and the drain D2 are on opposite sides of the second channel CH2. In some embodiments, the source S1 and the drain D2 share a common epitaxial structure, because the source S1 and drain D2 are formed in a common epitaxial source/drain region 140A. Since the epitaxial source/drain region 140B and the epitaxial source/drain region 160B are separated from each other by the second isolation structure 150B, the epitaxial source/drain region 140B can be vertically isolated from the epitaxial source/drain region 160B. Therefore, the drain D1 of the first transistor T1 is isolated from the source S2 of the transistor T2, but the source S1 of the first transistor T1 is electrically coupled to the drain D2 of the transistor T2, so that the first transistor T1 is connected in series with the second transistor T2.

The second transistor T2 is over the first transistor T1. The first transistor T1 and the second transistor T2 are connected in series with the third transistor T3 and the fourth transistor T4. In some embodiments, the lower one of the second semiconductor layers 118 functions as a channel of the third transistor T3 and can be referred to as a third channel CH3, and the upper one of the second semiconductor layers 118 functions as a channel of the fourth transistor T4 and can be referred to as a fourth channel CH4. The spacer material 190 is vertically between the second channel CH2 and the third channel CH3. A middle part of the epitaxial source/drain region 160B is connected to the third channel CH3 and can thus serve as a drain D3 of the third transistor T3. A lower part of the epitaxial source/drain region 160A is connected to the third channel CH3, and can thus serve as a source S3 of the third transistor T3, which is coupled to a low power supply voltage VSS. The source S3 and the drain D3 are on opposite sides of the third channel CH3. The first isolation structure 150A is disposed vertically between the drain D2 and the source S3. An upper part of the epitaxial source/drain region 160A is connected to the fourth channel CH4, and can thus serve as a source S4 of the fourth transistor T4, which is coupled to the low power supply voltage VSS. An upper part of the epitaxial source/drain region 160B is connected to the fourth channel CH4, and can thus serve as a drain D4 of the fourth transistor T4. That is, the drain D4 and the drain D3 share a common epitaxial structure. The source S4 and the drain D4 are on opposite sides of the fourth channel CH4. Therefore, the third transistor T3 can be connected in parallel with the fourth transistor T4.

The third transistor T3 and the fourth transistor T4 are pre-amplifiers that are variable gain amplifiers and have a broad power spectrum. An input signal (i.e., gain control signal) 304 can be generated and used to control the gain of the third transistor T3 and the fourth transistor T4 to achieve a desired gain. The third transistor T3 and the fourth transistor T4 produce a pre-amplified signal 302 which is passed through the second transistor T2. The gain of the third transistor T3 and the fourth transistor T4 are variable in order to provide a first amount of gain depending on a desired output power level for an amplified output signal 306. The first transistor T1 and the second transistor T2 may be biased by a control voltage 308 to control the impedance at a node 310. The first transistor T1 and the second transistor T2 then amplifies the pre-amplified signal 302 to generate an amplified output signal 306, providing a remainder of the required gain as well as the power amplification. The amplified output signal 306 at the node 310 is a product of the current that passes through the transistor T1 and the impedance at node 310.

As discussed previously, by disposing the second isolation structure 150B between the epitaxial source/drain region 140B and the epitaxial source/drain region 140B, the first transistor T1 can be connected in series with the second transistor T2. Because the first transistor T1 is connected in series with the second transistor T2, an effective gate length of a combination of the first and second transistors T1, T2 is increased. The effective gate length of a combination of the first transistor T1 and the second transistor T2 is different from an effective gate length of the third transistor T3 or an effective gate length of the fourth transistor T4. The increased effective gate length can provide an increased output resistance, which allows for an increased control voltage 308 and is beneficial for the transistor array for the PA 300 to provide high output power. The first transistor T1 can tolerate high voltage swing at the node 310. Since the first transistor T1 and the second transistor T2 are vertically stacked, the footprint of the PA 300 is not increased. That is, the PA 300 can have a small array size and a decreased distance for electrical routing, resulting in a reduced parasitic capacitance.

The source S2 of the second transistor T2 (i.e., the lower part of the epitaxial source/drain region 160B) and the drain D3 of the third transistor T3 (i.e., the middle part of the epitaxial source/drain region 160B) are formed in a common epitaxial source/drain region. Because the source S2 of the second transistor T2 (i.e., the lower part of the epitaxial source/drain region 160B) and the drain D3 of the third transistor T3 (i.e., the middle part of the epitaxial source/drain region 160B) share a common epitaxial structure, no additional metal line is required to connect them together. Therefore, a metal line resistance and a contact resistance between source/drain connections can be omitted. A high performance at radio frequency (RF) of the PA 300 can thus be achieved.

In the configuration of the PA 300, the first transistor T1 and the second transistor T2 tolerate the high voltage swing at the node 310, and the third transistor T3 and the fourth transistor T4 provide the gain. In some embodiments where the first, second, third and fourth transistors T1, T2, T3 and T4 are n-type transistors, transistors stacking to achieve vertically stacked high power nFET and high gain nFET is achieved.

Based on above discussions, it can be seen that the present disclosure offers advantages. It is understood, however, that other embodiments may offer additional advantages, and not all advantages are necessarily disclosed herein, and that no particular advantage is required for all embodiments. The present disclosure in various embodiments provides an integrated circuit including vertically stacked transistors on a semiconductor substrate. An advantage is that the isolation structure between epitaxial source/drain regions of vertically stacked transistors is formed, allowing the transistors to be connected in series with each other without increasing a footprint of the integrated circuit. Another advantage is that because the source of the second transistor (i.e., the lower part of the epitaxial source/drain region) and the drain of the third transistor (i.e., the middle part of the epitaxial source/drain region) share a common epitaxial structure, no additional metal line is required to connect them together. Therefore, a metal line resistance and a contact resistance between source/drain connections can be omitted. A high performance at radio frequency (RF) of the power amplifier can thus be achieved.

In some embodiments, a device includes a semiconductor substrate, a first transistor, a second transistor over the first transistor and a first isolation structure. The first transistor is on the semiconductor substrate. The first transistor comprises a first channel, a first source and a first drain. The first source and the first drain are on opposite sides of the first channel. The second transistor comprises a second channel, a second source and a second drain. The second source and the second drain are on opposite sides of the second channel. The first transistor is connected in series with the second transistor. The first isolation structure is vertically between the first drain and the second source. In some embodiments, the first source and the second drain share a common epitaxial structure. In some embodiments, the device further comprises a third transistor over the second transistor. The third transistor comprises a third channel, a third drain and a third source. The third drain and the third source are on opposite sides of the third channel. The third drain and the second source share a common epitaxial structure. In some embodiments, the device further comprises a fourth transistor over the third transistor. The fourth transistor comprises a fourth channel, a fourth drain and a fourth source. The fourth drain and the fourth source are on opposite sides of the fourth channel. The fourth drain and the third drain share a common epitaxial structure. In some embodiments, the fourth source and the third source share a common epitaxial structure. In some embodiments, the device further comprises a second isolation structure vertically between the second drain and the third source. In some embodiments, the device further comprises a spacer material vertically between the second channel and the third channel. In some embodiments, the spacer material extends along a sidewall of the first channel and a sidewall of the second channel.

In some embodiments, a device comprises a substrate, a plurality of first semiconductor layers, a first metal gate structure, a plurality of second semiconductor layers and a second metal gate structure. The plurality of first semiconductor layers is arranged one above another over the substrate. The first metal gate structure wraps around the plurality of first semiconductor layers. The plurality of second semiconductor layers is arranged one above another on the substrate. The second metal gate structure wraps around the plurality of second semiconductor layers and is spaced apart from the first metal gate structure. When viewed from a cross-sectional view, the first metal gate structure has a first height, the second metal gate structure has a second height less than the first height. When viewed from a top view, the second metal gate structure has a top surface area different from a top surface area of the first metal gate structure. In some embodiments, the device further includes first epitaxial structures disposed on opposite sides of the plurality of first semiconductor layers, and wherein the first epitaxial structures have top surfaces at different elevations. In some embodiments, the device further includes a first isolation structure and a second isolation structure. The first isolation structure is on a first one of the first epitaxial structures. The second isolation structure is on a second one of the first epitaxial structures. The first isolation structure and the second isolation structure have top surfaces at different elevations. In some embodiments, the device further includes second epitaxial structures disposed on opposite sides of the plurality of second semiconductor layers. The second epitaxial structures have bottom surfaces at different elevations. In some embodiments, one of the second epitaxial structures interfaces a sidewall of a top one of the plurality of first semiconductor layers. In some embodiments, the device further comprises a spacer material extending along sidewalls of the plurality of first semiconductor layers and a bottom surface of the second metal gate structure. In some embodiments, the device further comprises an inner spacer spacing the first metal gate structure apart from the plurality of second semiconductor layers. In some embodiments, when viewed from the cross-sectional view, the spacer material is wider than the inner spacer. In some embodiments, when viewed from the cross-sectional view, the inner spacer has a height less than a maximum height of the spacer material.

In some embodiments, a method of forming a device comprises the following steps. A stack is formed on a semiconductor substrate. The stack comprises a first multi-layer stack, a first sacrificial layer and a second multi-layer stack stacked on the semiconductor substrate in sequence. The first multi-layer stack comprises alternating stacked first semiconductor layers and second sacrificial layers. The second multi-layer stack comprises alternating stacked second semiconductor layers and third sacrificial layers. A first epitaxial source/drain region and a second epitaxial source/drain region are formed on the semiconductor substrate. The first epitaxial source/drain region and the second epitaxial source/drain region are on opposite sidewalls of the stack, respectively. The first epitaxial source/drain region has a height greater than a height of the second epitaxial source/drain region. The second sacrificial layers are replaced with a first metal gate structure. The third sacrificial layers are replaced with a second metal gate structure. In some embodiments, the method further comprises the following steps. Prior to replacing the third sacrificial layers with the second metal gate structure, sidewalls of the second semiconductor layers are etched without etching the first semiconductor layers. Inner spacers are formed on the etched sidewalls of the second semiconductor layers. In some embodiments, the method further comprises the following steps. A first isolation structure is formed over the first epitaxial source/drain region and a second isolation structure is formed over the second epitaxial source/drain region. A third epitaxial source/drain region is formed over the first isolation structure and a fourth epitaxial source/drain region is formed over the second isolation structure. The third epitaxial source/drain region has a height less than a height of the fourth epitaxial source/drain region.

The foregoing outlines feature of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A device, comprising:
a semiconductor substrate;
a first transistor on the semiconductor substrate, wherein the first transistor comprises a first channel, a first source and a first drain, the first source and the first drain are on opposite sides of the first channel;
a second transistor over the first transistor, wherein the second transistor comprises a second channel, a second source and a second drain, the second source and the second drain are on opposite sides of the second channel, and the first transistor is connected in series with the second transistor; and
a first isolation structure vertically between the first drain and the second source.

2. The device of claim 1, wherein the first source and the second drain share a common epitaxial structure.

3. The device of claim 1, further comprising:
a third transistor over the second transistor, wherein the third transistor comprises a third channel, a third drain and a third source, the third drain and the third source are on opposite sides of the third channel, and the third drain and the second source share a common epitaxial structure.

4. The device of claim 3, further comprising:
a fourth transistor over the third transistor, wherein the fourth transistor comprises a fourth channel, a fourth drain and a fourth source, the fourth drain and the fourth source are on opposite sides of the fourth channel, and the fourth drain and the third drain share a common epitaxial structure.

5. The device of claim 4, wherein the fourth source and the third source share a common epitaxial structure.

6. The device of claim 3, further comprising:
a second isolation structure vertically between the second drain and the third source.

7. The device of claim 3, further comprising:
a spacer material vertically between the second channel and the third channel.

8. The device of claim 7, wherein the spacer material extends along a sidewall of the first channel and a sidewall of the second channel.

9. A device, comprising:
a substrate;
a plurality of first semiconductor layers arranged one above another over the substrate;
a first metal gate structure wrapping around the plurality of first semiconductor layers;
a plurality of second semiconductor layers arranged one above another on the substrate; and
a second metal gate structure wrapping around the plurality of second semiconductor layers, and spaced apart from the first metal gate structure, wherein when viewed from a cross-sectional view, the first metal gate structure has a first height, the second metal gate structure has a second height less than the first height, and wherein when viewed from a top view, the second metal gate structure has a top surface area different from a top surface area of the first metal gate structure.

10. The device of claim 9, further comprising:
first epitaxial structures disposed on opposite sides of the plurality of first semiconductor layers, and wherein the first epitaxial structures have top surfaces at different elevations.

11. The device of claim 10, further comprising:
a first isolation structure on a first one of the first epitaxial structures; and
a second isolation structure on a second one of the first epitaxial structures, wherein the first isolation structure and the second isolation structure have top surfaces at different elevations.

12. The device of claim 9, further comprising:
second epitaxial structures disposed on opposite sides of the plurality of second semiconductor layers, and wherein the second epitaxial structures have bottom surfaces at different elevations.

13. The device of claim 12, wherein one of the second epitaxial structures interfaces a sidewall of a top one of the plurality of first semiconductor layers.

14. The device of claim 9, further comprising:
a spacer material extending along sidewalls of the plurality of first semiconductor layers and a bottom surface of the second metal gate structure.

15. The device of claim 14, further comprising:
an inner spacer spacing the first metal gate structure apart from the plurality of second semiconductor layers.

16. The device of claim 15, wherein when viewed from the cross-sectional view, the spacer material is wider than the inner spacer.

17. The device of claim 15, wherein when viewed from the cross-sectional view, the inner spacer has a height less than a maximum height of the spacer material.

18. A method of forming a device, comprising:
forming a stack on a semiconductor substrate, wherein the stack comprises a first multi-layer stack, a first sacrificial layer and a second multi-layer stack stacked on the semiconductor substrate in sequence, the first multi-layer stack comprises alternating stacked first semiconductor layers and second sacrificial layers, and the second multi-layer stack comprises alternating stacked second semiconductor layers and third sacrificial layers;
forming a first epitaxial source/drain region and a second epitaxial source/drain region on the semiconductor substrate, wherein the first epitaxial source/drain region and the second epitaxial source/drain region are on opposite sidewalls of the stack, respectively, and the first epitaxial source/drain region has a height greater than a height of the second epitaxial source/drain region;
replacing the second sacrificial layers with a first metal gate structure; and
replacing the third sacrificial layers with a second metal gate structure.

19. The method of claim 18, further comprising:
prior to replacing the third sacrificial layers with the second metal gate structure, etching sidewalls of the second semiconductor layers without etching the first semiconductor layers; and
forming inner spacers on the etched sidewalls of the second semiconductor layers.

20. The method of claim 19, further comprising:
forming a first isolation structure over the first epitaxial source/drain region and a second isolation structure over the second epitaxial source/drain region; and
forming a third epitaxial source/drain region over the first isolation structure and a fourth epitaxial source/drain region over the second isolation structure, wherein the third epitaxial source/drain region has a height less than a height of the fourth epitaxial source/drain region.
